(19) United States
(12) Patent Application Publication
(10) Pub. No.: US 2026/0271564 A1
(43) Pub. Date: Sep. 10, 2026

(54) DISPLAY APPARATUS AND ELECTRONIC DEVICE INCLUDING THE SAME

(71) Applicant: Samsung Display Co., Ltd., Yongin-si (KR)

(72) Inventors: Sujin Kim, Yongin-si (KR); Junwon Choi, Yongin-si (KR); Donghyun Kim, Yongin-si (KR); Chulkyu Kang, Yongin-si (KR); Seonkyoon Mok, Yongin-si (KR); Buyoung Park, Yongin-si (KR)

(21) Appl. No.: 19/561,089

(22) Filed: Mar. 9, 2026

(30) Foreign Application Priority Data
Mar. 10, 2025 (KR) 10-2025-0030783
Jul. 8, 2025 (KR) 10-2025-0091717

(51) Int. Cl. H10K 59/131; H10K 59/121

(52) U.S. Cl. CPC H10K 59/131; H10K 59/1213

(57) ABSTRACT

A display apparatus includes: a substrate including a display area, in which a first pixel and a second pixel respectively emitting light of different wavelengths from each other are disposed, and a peripheral area; a first common voltage line disposed in the display area and including a plurality of pad units spaced apart from each other by a predetermined interval; a second common voltage line disposed in the display area and extending in a second direction to overlap the second pixel; and a third common voltage line disposed in the display area and extending in the second direction to overlap the first pixel, where the second common voltage line is electrically connected to the plurality of pad units of the first common voltage line through a contact portion in an area where the second common voltage line overlaps the plurality of pad units.

This application claims priority to Korean Patent Application No. 10-2025-0030783, filed on March 10, 2025, and Korean Patent Application No. 10-2025-0091717, filed on July 8, 2025, and all the benefits accruing therefrom under 35 U.S.C. §119, the contents of which in their entirety is herein incorporated by reference.

### BACKGROUND

### 1. Field

The disclosure relates to a display apparatus and an electronic device including the same.

### 2. Description of the Related Art

Recently, display apparatuses are being used for various purposes. Also, as the range of applications of display apparatuses is increased, the demand for high-resolution display apparatuses is increasing. In order to manufacture high-resolution display apparatuses, it is desired to arrange various electronic elements in a substantially narrow area.

### SUMMARY

Embodiments of the disclosure are directed to providing a display apparatus with improved display quality and an electronic device including the display apparatus. However, the embodiments are examples and do not limit the scope of the disclosure.

Additional features will be set forth in part in the description which follows and, in part, will be apparent from the description, or may be learned by practice of the presented embodiments of the disclosure.

In an embodiment of the disclosure, a display apparatus includes: a substrate including a display area and a peripheral area outside the display area, where a first pixel and a second pixel that emit light of different wavelengths are disposed; a first common voltage line disposed in the display area, extending in a first direction, and including a plurality of pad units spaced apart from each other by a predetermined interval; a second common voltage line disposed in the display area and extending in a second direction intersecting the first direction to overlap the second pixel; and a third common voltage line disposed in the display area and extending in the second direction to overlap the first pixel, where the second common voltage line is electrically connected to the plurality of pad units of the first common voltage line through a contact portion in an area where the second common voltage line overlaps the plurality of pad units.

In an embodiment, the second pixel may be provided in plural, where the plurality of pad units are alternately arranged with the plurality of second pixels arranged in the second direction.

In an embodiment, the second pixel may emit light having a blue wavelength.

In an embodiment, an organic insulating layer may be disposed between the first common voltage line and the second common voltage line, where the contact portion is provided by a contact hole defined in the organic insulating layer.

In an embodiment, the plurality of pad units may include a first pad unit and a second pad unit, where a first contact portion corresponding to the first pad unit is disposed at a central portion of the first pad unit.

In an embodiment, the second pad unit may include a protruding portion protruding in at least one direction, where a second contact portion corresponding to the second pad unit is disposed in the protruding portion.

In an embodiment, at least one insulating layer may be further disposed on the plurality of pad units, where the at least one insulating layer defines an opening through which a central portion of the second pad unit is exposed.

In an embodiment, in a plan view, an area of the opening may be greater than an area of the second contact portion.

In an embodiment, in a plan view, the second contact portion and the opening may be spaced apart from each other.

In an embodiment, the display apparatus may further include a fourth common voltage line overlapping at least a part of the opening and extending in the second direction, in a plan view.

In an embodiment, the fourth common voltage line may include a first sub-common voltage line and a second sub-common voltage line, and the first sub-common voltage line and the second sub-common voltage line may include a connection portion that connects the first sub-common voltage line to the second sub-common voltage line in a partial region.

In an embodiment, the connection portion may be disposed to overlap the second pad unit.

In an embodiment, the second pixel may have a second emission area, where, in a plan view, the second common voltage line is disposed in a symmetric shape passing through a central portion of the second emission area of the second pixel.

In an embodiment, the display apparatus may further include a first upper driving voltage line and a second upper driving voltage line disposed in the display area, extending in the second direction, and spaced apart from each other in a plan view.

In an embodiment, the second upper driving voltage line may include a plurality of openings.

In an embodiment, each of the plurality of openings may be defined between a first emission area of the first pixel and a second emission area of the second pixel.

In an embodiment, the first pixel may include a first light-emitting element and a first pixel circuit,

In an embodiment, the first light-emitting element may include a first pixel electrode, a counter electrode disposed on the first pixel electrode, and an intermediate layer including an emission layer disposed between the first pixel electrode and the counter electrode, where the first common voltage line has a same material as that of the first pixel electrode.

In an embodiment, the first pixel circuit may include: a thin-film transistor including a semiconductor layer, a gate electrode having at least a part overlapping the semiconductor layer, and a first conductive layer disposed on the gate electrode and electrically connected to the semiconductor layer; and a second conductive layer disposed on the thin-film transistor, where the second common voltage line includes a same material as that of the second conductive layer.

In an embodiment, the third common voltage line may include a same material as that of the second conductive layer.

In an embodiment, the second common voltage line and the third common voltage line may be disposed in a same layer.

In an embodiment, the display apparatus may further include a common voltage supply line disposed in the peripheral area and disposed along an outer edge of the display area, where the first common voltage line further includes a connection line extending in the first direction toward the peripheral area and electrically connected to the common voltage supply line.

In an embodiment, the connection line may be integrally formed (or unitary) with the first common voltage line.

In an embodiment, the connection line may be disposed in a different layer from the first common voltage line.

In an embodiment, the connection line may be disposed in a different layer from the common voltage supply line.

In an embodiment, the common voltage supply line may be disposed in a same layer as the first common voltage line.

In an embodiment, the common voltage supply line may include a plurality of holes.

In an embodiment, the peripheral area may include a first peripheral area and a second peripheral area respectively disposed on a side and an opposite side with the display area therebetween, and a third peripheral area and a fourth peripheral area connecting the first peripheral area to the second peripheral area with the display area therebetween, where the common voltage supply line includes a main voltage line disposed in the first peripheral area, the second peripheral area, and the third peripheral area.

In an embodiment, a first sub-voltage line extending in the first direction may be further disposed in the third peripheral area, where an end of the first sub-voltage line is electrically connected to the main voltage line.

In an embodiment, the first sub-voltage line may be disposed between the main voltage line and the display area.

In an embodiment, the second common voltage line may extend to the third peripheral area along the second direction and may be electrically connected to the first sub-voltage line.

In an embodiment, a second sub-voltage line extending in the first direction may be further disposed in the fourth peripheral area, where an end of the second sub-voltage line is electrically connected to the main voltage line.

In an embodiment, the second common voltage line may extend to the fourth peripheral area along the second direction and may be electrically connected to the second sub-voltage line.

In an embodiment, the first pixel may include a first light-emitting element and a first pixel circuit,

In an embodiment, the first pixel circuit may include a thin-film transistor including a semiconductor layer, a gate electrode having at least a part overlapping the semiconductor layer, and a first conductive layer disposed on the gate electrode and electrically connected to the semiconductor layer, where the first sub-voltage line and the second sub-voltage line include a same material as that of the first conductive layer.

In an embodiment of the disclosure, an electronic device includes: a display apparatus; and a housing in which the display apparatus is accommodated, where the display apparatus includes: a substrate including a display area and a peripheral area outside the display area, where in the display area, a first pixel and a second pixel emitting light of different wavelengths are disposed; a first common voltage line disposed in the display area, extending in a first direction, and including a plurality of pad units spaced apart from each other by a predetermined interval; a second common voltage line disposed in the display area and extending in a second direction intersecting the first direction to overlap the second pixel; and a third common voltage line disposed in the display area and extending in the second direction to overlap the first pixel, where the second common voltage line is electrically connected to the plurality of pad units of the first common voltage line through a contact portion in an area where the second common voltage line overlaps the plurality of pad units.

In an embodiment, the electronic device may further include a processor, where the display apparatus further includes a controller which receives a power control signal from the processor and outputs a control signal based on the power control signal, and a power supply circuit which generates a driving voltage based on the control signal of the controller.

Other embodiments, features, and advantages of the disclosure will become more apparent from the drawings, the claims, and the detailed description.

These general and illustrative embodiments may be implemented by a system, a method, a computer program, or any combination thereof.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a block diagram illustrating an embodiment of an electronic device;

FIGS. 2 to 4 are schematic views illustrating embodiments of an electronic device;

FIGS. 5A and 5B are plan views schematically illustrating an embodiment of a display apparatus;

FIG. 6 is a plan view schematically illustrating an embodiment of a display apparatus;

FIG. 7 is an equivalent circuit diagram schematically illustrating an embodiment of a pixel circuit and a light-emitting diode of a pixel of the disclosure;

FIG. 8 is a plan view schematically illustrating an embodiment of a part of a display area of a display apparatus of the disclosure;

FIG. 9 is a layout diagram schematically illustrating an embodiment of a structure of pixel circuits in pixels of the disclosure;

FIGS. 10 to 16 are layout diagrams illustrating conductive patterns constituting the pixel circuit of FIG. 9, according to respective layers;

FIG. 17 is a cross-sectional view schematically illustrating an embodiment of a cross-section including a pad unit of the disclosure;

FIG. 18 is a cross-sectional view schematically illustrating an embodiment of a part of a structure of a pixel circuit of the disclosure;

FIG. 19 is a cross-sectional view schematically illustrating an embodiment of a part of a display apparatus of the disclosure;

FIG. 20 is a cross-sectional view schematically illustrating an embodiment of a part of a display apparatus of the disclosure;

FIG. 21 is a cross-sectional view schematically taken along line C-C’ of FIG. 20;

FIG. 22 is a cross-sectional view schematically illustrating an embodiment of a part of a display apparatus of the disclosure;

FIG. 23 is a plan view schematically illustrating an embodiment of a second source-drain layer of the disclosure;

FIG. 24 is a plan view schematically illustrating an embodiment of a pixel electrode layer of the disclosure;

FIG. 25 is a plan view schematically illustrating an embodiment of a display apparatus of the disclosure; and

FIGS. 26 and 27 are enlarged views schematically illustrating a part of the display apparatus of FIG. 25.

### DETAILED DESCRIPTION

Reference will now be made in detail to embodiments, examples of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

As the disclosure allows for various changes and numerous embodiments, illustrative embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments of the disclosure will be described in detail with reference to the accompanying drawings, where the same or corresponding elements are denoted by the same reference numerals throughout and a repeated description thereof is omitted.

Although the terms "first," "second," “1-1” (e.g., referring to a first part of a first element), “1-2” (e.g., referring to a second part of the first element), etc., may be used to describe various elements, these elements should not be limited by these terms, and these terms are only used to distinguish one element from another. Also, the singular forms "a," "an," and "the" are intended to include the plural forms as well, unless the context clearly indicates otherwise.

It will be understood that the terms "including" and "having" are intended to indicate the existence of the features or elements described in the specification, and are not intended to preclude the possibility that one or more other features or elements may exist or may be added. It will be further understood that, when a layer, region, or component is also referred to as being "on" another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

The x-axis, the y-axis and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an illustrative embodiment may be implemented differently, a predetermined process order may be different from the described order. For example, two consecutively described processes may be performed substantially at the same time or may be performed in an order opposite to the described order.

A display apparatus in an embodiment may be applied to various electronic devices. An electronic device in an embodiment may include the display apparatus, and may further include a module or a device having an additional function in addition to the display apparatus.

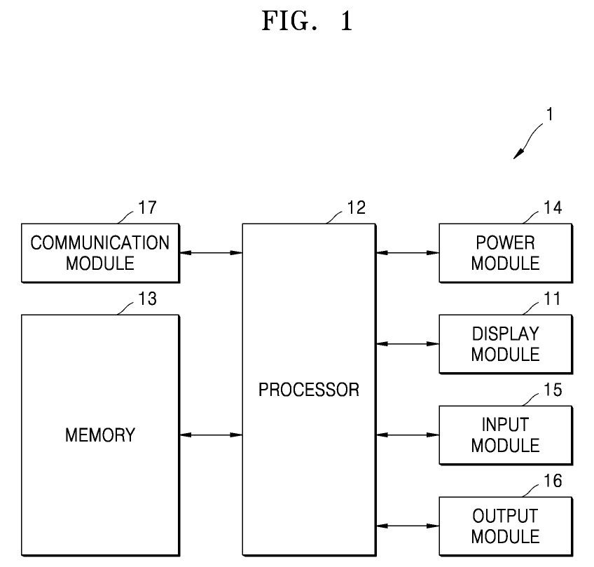

FIG. 1 is a block diagram illustrating an embodiment of an electronic device.

Referring to FIG. 1, an electronic device 1 in an embodiment may include a display module 11, a processor 12, a memory 13, and a power module 14. The electronic device 1 may further include an input module 15, a non-image output module 16, and/or a communication module 17.

The electronic device 1 may output various information as an image through the display module 11. When the processor 12 executes an application stored in the memory 13, image information provided by the application may be provided to a user through the display module 11. The power module 14 may include a power supply module, such as a power adaptor or a battery device, and a power conversion module which converts power supplied by the power supply module and generates power desired for an operation of the electronic device 1. The input module 15 may provide input information to the processor 12 and/or the display module 11. The non-image output module 16 may receive information, e.g., sound, haptic, or emission information, other than an image received from the processor 12, and may provide the information to the user. The communication module 17 is a module for transmitting/receiving information between the electronic device 1 and an external device, and may include a receiver and a transmitter.

At least one of the components of the electronic device 1 described above may be included in the display apparatus according to the embodiments described above. Also, some of individual modules functionally included in one module may be included in the display apparatus and remaining (the other) individual modules may be provided separately from the display apparatus. In an embodiment, the display apparatus may include the display module 11, and the processor 12, the memory 13, and the power module 14 may be provided as other devices in the electronic device 1, rather than the display apparatus, for example.

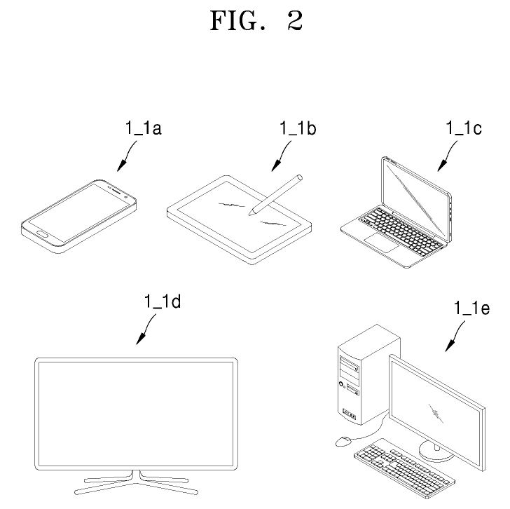

FIGS. 2 to 4 are schematic views illustrating embodiments of an electronic device. FIGS. 2 to 4 illustrate examples of various electronic devices to which a display apparatus is applied, in embodiments.

FIG. 2 illustrates a smartphone 1_1a, a tablet personal computer 1_1b, a laptop computer 1_1c, a television (“TV”) 1_1d, and a monitor 1_1e for a desk as examples of an electronic device.

The smartphone 1_1a may include an input module, such as a touch sensor, and a communication module, in addition to the display module 11 (refer to FIG. 1). The smartphone 1_1a may process information received through the communication module or other input modules and may display the information through the display module of the display apparatus.

Each of the tablet personal computer 1_1b, the laptop computer 1_1c, the TV 1_1d, and the monitor 1_1e for a desk may also include a display module and an input module, like the smartphone 1_1a, and may further include a communication module when desired. In an embodiment, the display apparatus may be disposed in a housing of the electronic device.

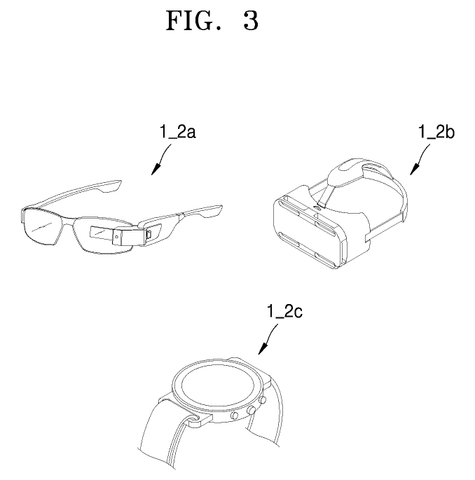

FIG. 3 illustrates a case where an electronic device including a display module is applied to a wearable electronic device. Examples of the wearable electronic device may include smart glasses 1_2a, a head-mounted display 1_2b, and a smart watch 1_2c.

The smart glasses 1_2a and the head-mounted display 1_2b may include a display module that emits a display image and a reflector that reflects the emitted display screen and provides the display screen to a user’s eyes, thereby providing a screen of virtual reality or augmented reality to the user.

The smart watch 1_2c may include a biometric sensor as an input device, and may provide biometric information recognized through the biometric sensor to the user through a display module.

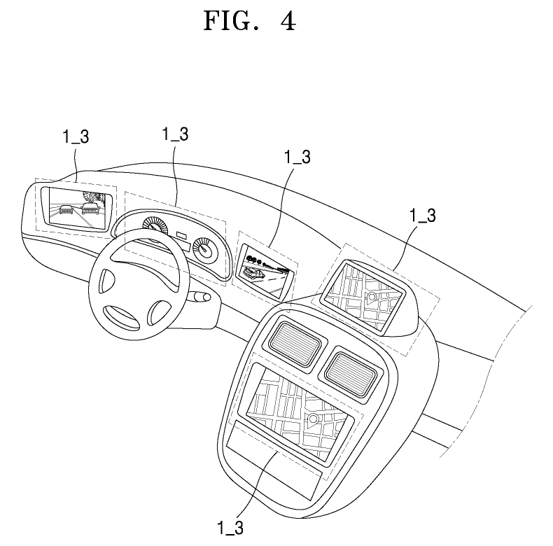

FIG. 4 illustrates a case where an electronic device including a display module is applied to a vehicle. In an embodiment, an electronic device 1_3 may be applied to a dashboard or a center fascia of a vehicle, or may be applied to a center information display (“CID”) disposed on a dashboard of a vehicle or a room mirror display that replaces a side-view mirror, for example.

Although not shown, examples of an electronic device to which a display apparatus in embodiments is applied may include not only devices that mainly display screens, such as an advertisement board, an electronic display board, and a game console, but also various home appliances that display information through a display module, such as a refrigerator, a washing machine, a drier, an air conditioner, and a robot cleaner. Also, when a display module has a function of transmitting light, the display module may be applied to an electronic device such as a smart window or a transparent display apparatus that displays both a background and a display image. Types of an electronic device in an embodiment are not limited to the examples described above, and various other electronic devices may also be applied.

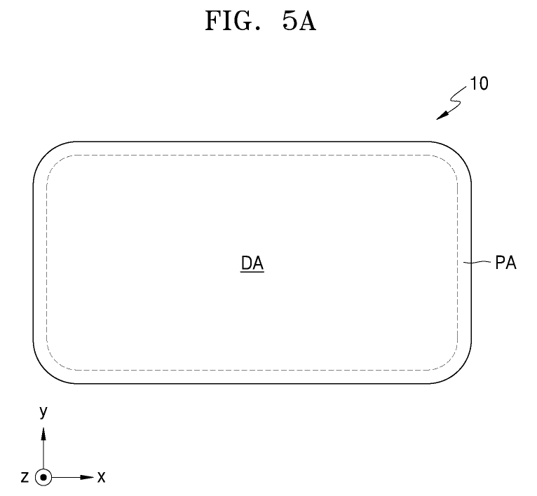

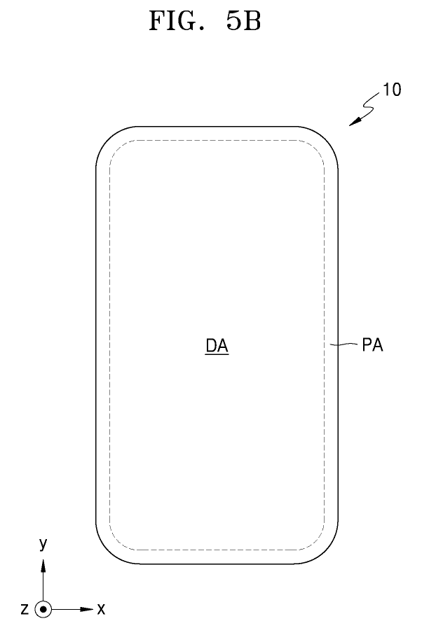

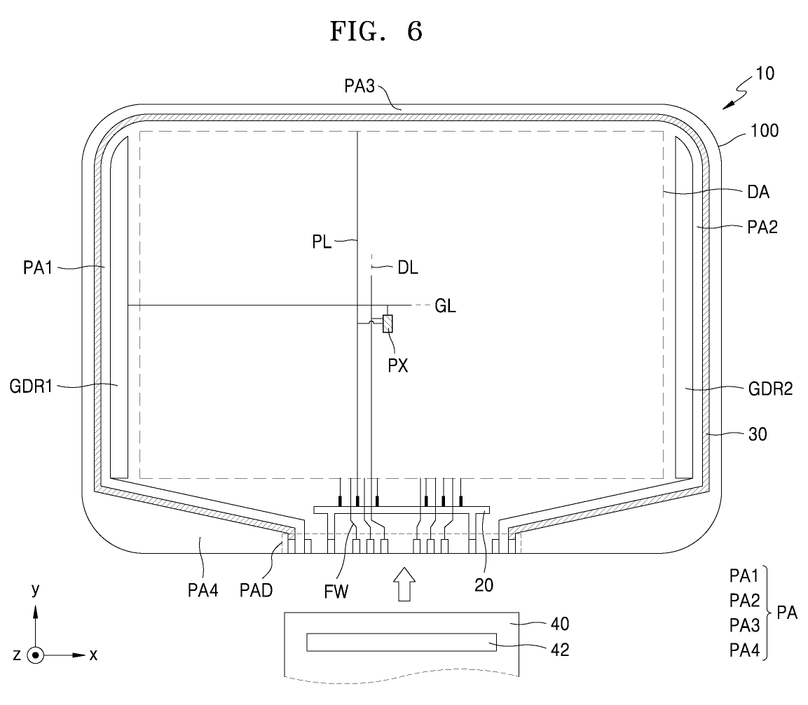

FIGS. 5A and 5B are plan views schematically illustrating an embodiment of a display apparatus. FIG. 6 is a plan view schematically illustrating an embodiment of a display apparatus.

A display apparatus 10 described below may be included in the electronic device 1 described with reference to FIGS. 1 to 4. The display apparatus 10 may include the display module 11 described with reference to FIG. 1.

Referring to FIGS. 5A and 5B, the display apparatus 10 may include a display area DA where an image is displayed and a peripheral area PA outside the display area DA. The display area DA may be entirely surrounded by the peripheral area PA.

In a plan view, the display area DA may have a quadrangular shape, e.g., rectangular shape. In another embodiment, the display area DA may have a polygonal shape (e.g., a triangular shape, a pentagonal shape, or a hexagonal shape), a circular shape, an elliptical shape, or an irregular shape. The display area DA may have a shape with rounded corners. In an embodiment, as shown in FIG. 5A, the display apparatus 1 may have the display area DA in which a length in a first direction (e.g., an x-axis direction) is greater than a length in a second direction (e.g., a y-axis direction). In another embodiment, as shown in FIG. 5B, the display apparatus 10 may have the display area DA in which a length in the second direction (e.g., the y-axis direction) is greater than a length in the first direction (e.g., the x-axis direction).

Hereinafter, FIG. 6 will be described assuming that the display area DA has the same shape as that described with reference to FIG. 5A.

Referring to FIG. 6, the peripheral area PA may include a first peripheral area PA1, a second peripheral area PA2, a third peripheral area PA3, and a fourth peripheral area PA4. The first peripheral area PA1 and the second peripheral area PA2 may be respectively disposed on one side and an opposite side (e.g., a left side and a right side) with the display area DA therebetween. The third peripheral area PA3 and the fourth peripheral area PA4 may be disposed to connect the first peripheral area PA1 and the second peripheral area PA2 with the display area DA therebetween. In an embodiment, the third peripheral area PA3 and the fourth peripheral area PA4 may be disposed on an upper side and a lower side with the display area DA therebetween, for example.

Various components included in the display apparatus 10 may be disposed on a substrate 100. In the display area DA, a plurality of gate lines GL, a plurality of data lines DL, and a plurality of pixels PX connected to the plurality of gate lines GL and the plurality of data lines DL may be disposed.

The plurality of pixels PX may be arranged in any of various forms, such as a stripe arrangement, a pentile arrangement, a diamond arrangement, or a mosaic arrangement, to display an image. Each pixel PX may include an organic light-emitting diode (“OLED”) as a display element (i.e., a light-emitting element such as a light-emitting diode), and the OLED may be connected to a pixel circuit. The pixel circuit may include a plurality of transistors and at least one capacitor. The pixel PX may emit light, e.g., red light, green light, blue light, or white light, through the OLED. Each pixel PX may be connected to a corresponding gate line among the plurality of gate lines GL and a corresponding data line among the plurality of data lines DL.

The gate line GL may extend in the first direction (e.g., the x-axis direction) and may be connected to the pixels PX disposed in the same row. The gate line GL may transmit a gate signal to the pixels PX in the same row. The data line DL may extend in the second direction (e.g., the y-axis direction) and may be connected to the pixels PX disposed in the same column. The data line DL may transmit a data signal to each of the pixels PX in the same column in synchronization with the gate signal. Each pixel PX may be connected to a driving voltage line PL to receive a driving voltage ELVDD. The driving voltage line PL may extend in the second direction (e.g., the y-axis direction) and may be connected to the pixels PX disposed in the same column.

Although the pixel PX is connected to one gate line GL in FIG. 6, the disclosure is not limited thereto. The pixel PX may be connected to one or more gate lines GL.

The pixel circuits for driving the pixels PX may be respectively electrically connected to outer circuits disposed in the peripheral area PA In the peripheral area PA, a first gate driving circuit GDR1, a second gate driving circuit GDR2, a terminal unit PAD, a driving voltage supply line 20, and a common voltage supply line 30 may be disposed.

The first gate driving circuit GDR1 may be disposed in the first peripheral area PA1. The first gate driving circuit GDR1 may be connected to the plurality of gate lines GL, and may apply a gate signal to each of the pixel circuits for driving the pixels PX through the gate lines GL.

The second gate driving circuit GDR2 may be disposed in the second peripheral area PA2. That is, the second gate driving circuit GDR2 may be disposed opposite to the first gate driving circuit GDR1 with respect to the display area DA, and may be substantially parallel to the first gate driving circuit GDR1.

In an embodiment, the pixel circuits of the pixels PX of the display area DA may be electrically connected to the first gate driving circuit GDR1 and the second gate driving circuit GDR2. In another embodiment, some of the pixel circuits of the pixels PX of the display area DA may be electrically connected to the first gate driving circuit GDR1, and the rest may be electrically connected to the second gate driving circuit GDR2. In another embodiment, the second gate driving circuit GDR2 may be omitted.

The terminal unit PAD may be disposed on an edge of the substrate 100. The terminal unit PAD may be exposed without being covered by an insulating layer, and may be connected to a display circuit board 40. The display circuit board 40 may be a flexible printed circuit board (“FPCB”), for example.

A display driver 42 may be disposed on the display circuit board 40. The display driver 42 may be directly disposed on the substrate by a chip on glass (“COG”) or chip on plastic (“COP”) method.

The display driver 42 may include a data driving circuit. The data driving circuit may generate a data signal, and the generated data signal may be transmitted to the pixel circuits of the pixels PX through a fan-out line FW and the data line DL connected to the fan-out line FW. Also, the display driver 42 may include a power supply circuit, and the power supply circuit may supply a driving voltage ELVDD to the driving voltage supply line 20 and may supply a common voltage ELVSS to the common voltage supply line 30. The driving voltage ELVDD may be applied to the pixel circuits of the pixels PX through the driving voltage line PL connected to the driving voltage supply line 20, and the common voltage ELVSS may be applied to a counter electrode of the display element through the common voltage supply line 30. Also, the display driver 42 may include a controller, and the controller may receive a power control signal from the processor 12 and generate control signals transmitted to the first gate driving circuit GDR1, the second gate driving circuit GDR2, the data driving circuit, and the power supply circuit.

The driving voltage supply line 20 may be disposed at one side of the display area DA, e.g., in the fourth peripheral area PA4, may extend along the first direction (e.g., the x-axis direction), and may be connected to the terminal unit PAD.

The common voltage supply line 30 may be connected to the terminal unit PAD, and may partially surround the display area DA. In FIG. 6A, the common voltage supply line 30 has a loop shape with one side open to partially surround the display area DA in the first to third peripheral areas PA1, PA2, and PA3. In another embodiment, the common voltage supply line 30 may be disposed in the first to fourth peripheral areas PA1, PA2, PA3, and PA4 to completely surround the display area DA in a closed loop shape.

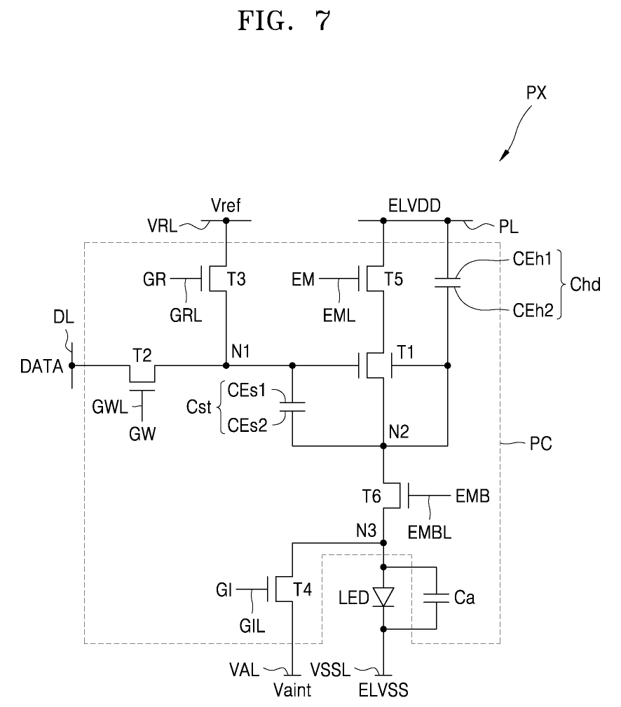

FIG. 7 is an equivalent circuit diagram schematically illustrating an embodiment of a pixel circuit and a light-emitting diode of a pixel of the disclosure.

Referring to FIG. 7, the pixel PX may include a light-emitting diode LED and a pixel circuit PC connected to the light-emitting diode LED. The pixel PX may refer to a sub-pixel, and the pixel circuit PC may refer to a sub-pixel circuit. Also, the light-emitting diode LED may be an OLED, for example.

The pixel circuit PC may include a plurality of transistors (e.g., thin-film transistors) and a plurality of capacitors.

In an embodiment, the pixel circuit PC may include first to sixth transistors T1, T2, T3, T4, T5, and T6, a storage capacitor Cst, and a hold capacitor Chd. The first transistor T1 may be also referred to as a driving transistor, the second transistor T2 may be also referred to as a switching transistor, the third transistor T3 may be also referred to as a compensation transistor, the fourth transistor T4 may be also referred to as an initialization transistor, the fifth transistor T5 may be also referred to as an operation control transistor, and the sixth transistor T6 may be also referred to as an emission control transistor. A first terminal (first electrode) of each of the first to sixth transistors T1, T2, T3, T4, T5, and T6 may be a source or a drain, and a second terminal (second electrode) may be a terminal different from the first terminal. In an embodiment, when the first terminal is a drain, the second terminal may be a source, for example.

In an embodiment, each of the plurality of transistors included in the pixel circuit PC may be an n-channel metal-oxide-semiconductor field-effect-transistor (“MOSFET”) (“NMOS”) including an oxide semiconductor layer. However, this is merely one of embodiments, and transistors of the disclosure are not limited thereto. In another embodiment, at least one of the first to sixth transistors T1, T2, T3, T4, T5, and T6 may be a p-channel MOSFET (“PMOS”), and the rest may be NMOSs. In an embodiment, the fifth transistor T5 may be a PMOS, and the first, second, third, fourth, and sixth transistors T1, T2, T3, T4, and T6 may be NMOSs, for example. In an alternative embodiment, the fifth transistor T5 and the sixth transistor T6 may be PMOSs, and the first, second, third, and fourth transistors T1, T2, T3, and T4 may be NMOSs. In an alternative embodiment, all of the first to sixth transistors T1, T2, T3, T4, T5, and T6 may be NMOSs or PMOSs. Hereinafter, the following will be described assuming that each of the first to sixth transistors T1, T2, T3, T4, T5, and T6 includes an NMOS including an oxide semiconductor.

The pixel circuit PC may include a plurality of wirings. In an embodiment, the pixel circuit PC may be electrically connected to a gate line GWL that transmits a gate signal GW, a reference gate line GRL that transmits a reference signal GR, a first emission control line EML that transmits a first emission control signal EM, an initialization gate line GIL that transmits an initialization signal GI, a second emission control line EMBL that transmits a second emission control signal EMB, and a data line DL that transmits a data signal DATA. The pixel circuit PC may be electrically connected to a driving voltage line PL that transmits a driving voltage ELVDD, a reference voltage line VRL that transmits a reference voltage Vref, and an initialization voltage line VAL that transmits an initialization voltage Vaint.

Each of the first terminal (or first electrode) and the second terminal (or second electrode) of each of the first to sixth transistors T1, T2, T3, T4, T5, and T6 may be a source (or a source electrode) or a drain (or a drain electrode) according to voltages of the first terminal and the second terminal. In an embodiment, according to voltages of the first terminal and the second terminal, the first terminal may be a drain and the second terminal may be a source, or the first terminal may be a source and the second terminal may be a drain, for example. Hereinafter, a node to which a 1-1 gate electrode of the first transistor T1 is connected may be defined as a first node N1, and a node to which the second terminal of the first transistor T1 is connected may be defined as a second node N2.

The first transistor T1 may be connected to the driving voltage line PL and the light-emitting diode LED. The first transistor T1 may be connected between the fifth transistor T5 and the sixth transistor T6. The first transistor T1 may include a first gate electrode, the first terminal, and the second terminal connected to the second node N2. The first transistor T1 may include the 1-1 gate electrode connected to the first node N1. The first transistor T1 may further include a 1-2 gate electrode connected to its second terminal. The 1-1 gate electrode and the 1-2 gate electrode may be disposed in different layers to face each other. In an embodiment, the 1-1 gate electrode and the 1-2 gate electrode of the first transistor T1 may face each other with a semiconductor layer therebetween, for example. In the specification, the first gate electrode of the first transistor T1 may refer to the 1-1 gate electrode involved in turning on and off the first transistor T1.

The 1-1 gate electrode of the first transistor T1 may be connected to the second terminal of the second transistor T2, the first terminal of the third transistor T3, and the storage capacitor Cst. The 1-2 gate electrode of the first transistor T1 may be connected to the first terminal of the sixth transistor T6, the storage capacitor Cst, and the hold capacitor Chd. The first terminal of the first transistor T1 may be connected to the driving voltage line PL via the fifth transistor T5, and the second terminal may be connected to a pixel electrode of the light-emitting diode LED via the sixth transistor T6. The first terminal of the first transistor T1 may be connected to the second terminal of the fifth transistor T5. The second terminal of the first transistor T1 may be connected to the first terminal of the sixth transistor T6, the storage capacitor Cst, and the hold capacitor Chd. The first transistor T1 may receive the data signal DATA according to a switching operation of the second transistor T2, and may control the amount of driving current flowing to the light-emitting diode LED.

The second transistor T2 may be connected to the data line DL and the first gate electrode of the first transistor T1. The second transistor T2 may include a second gate electrode connected to the gate line GWL, the first terminal connected to the data line DL, and the second terminal connected to the first node N1. The second terminal of the second transistor T2 may be connected to the first gate electrode of the first transistor T1, the first terminal of the third transistor T3, and the storage capacitor Cst. The second transistor T2 may be turned on by the gate signal GW transmitted through the gate line GWL to electrically connect the data line DL to the first node N1 and transmit the data signal DATA transmitted through the data line DL to the first node N1.

The third transistor T3 may be connected to the first gate electrode of the first transistor T1 and the reference voltage line VRL. The third transistor T3 may include a third gate electrode connected to the reference gate line GRL, the first terminal connected to a first node N1, and the second terminal connected to the reference voltage line VRL. The first terminal of the third transistor T3 may be connected to the first gate electrode of the first transistor T1, the second terminal of the second transistor T2, and the storage capacitor Cst. The third transistor T3 may be turned on by the reference signal GR transmitted through the reference gate line GRL to transmit the reference voltage Vref transmitted through the reference voltage line VRL to the first node N1.

The fourth transistor T4 may be connected to the sixth transistor T6 and the initialization voltage line VAL. The fourth transistor T4 may be connected between the light-emitting diode LED and the initialization voltage line VAL. The fourth transistor T4 may include a fourth gate electrode connected to the initialization gate line GIL, the first terminal connected to a third node N3, and the second terminal connected to the initialization voltage line VAL. The first terminal of the fourth transistor T4 may be connected to the second terminal of the sixth transistor T6 and the pixel electrode of the light-emitting diode LED. The fourth transistor T4 may be turned on by the initialization signal GI transmitted through the initialization gate line GIL to transmit the initialization voltage Vaint transmitted through the initialization voltage line VAL to the third node N3 and initialize the pixel electrode (e.g., an anode) of the light-emitting diode LED.

The fifth transistor T5 may be connected to the driving voltage line PL and the first transistor T1. The fifth transistor T5 may include a fifth gate electrode connected to the first emission control line EML, the first terminal connected to the driving voltage line PL, and the second terminal connected to the first terminal of the first transistor T1. The fifth transistor T5 may be turned on or turned off according to the first emission control signal EM transmitted through the first emission control line EML.

The sixth transistor T6 may be connected to the first transistor T1 and the light-emitting diode LED. The sixth transistor T6 may be connected between the second node N2 and the third node N3. The sixth transistor T6 may include a sixth gate electrode connected to the second emission control line EMBL, the first terminal connected to a second node N2, and the second terminal connected to the third node N3. The first terminal of the sixth transistor T6 may be connected to the second terminal of the first transistor T1, the storage capacitor Cst, and the hold capacitor Chd. The second terminal of the sixth transistor T6 may be connected to the first terminal of the fourth transistor T4 and the pixel electrode of the light-emitting diode LED. The sixth transistor T6 may be turned on or turned off according to the second emission control signal EMB transmitted through the second emission control line EMBL.

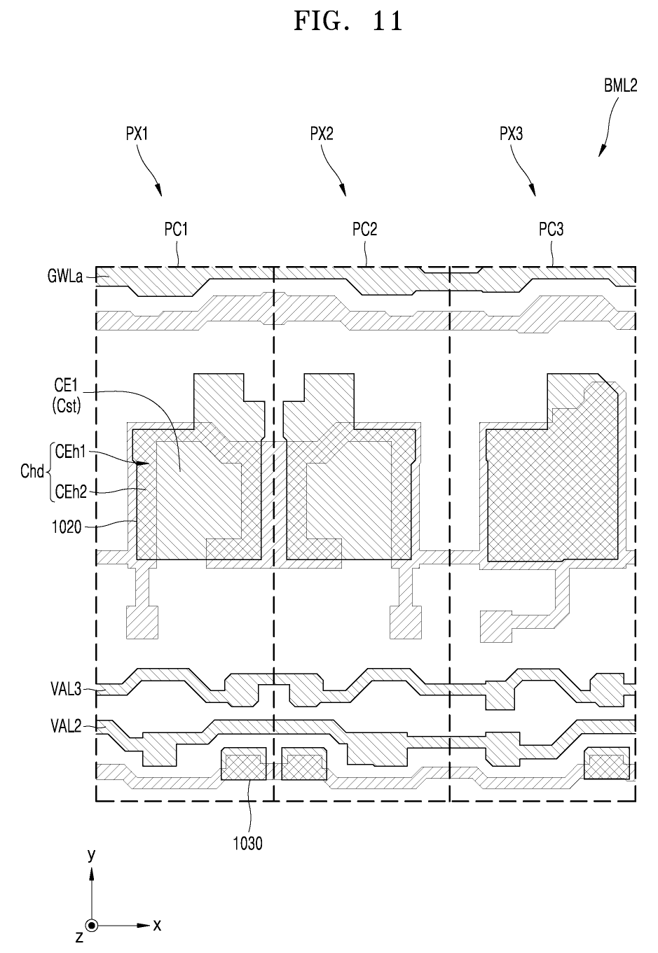

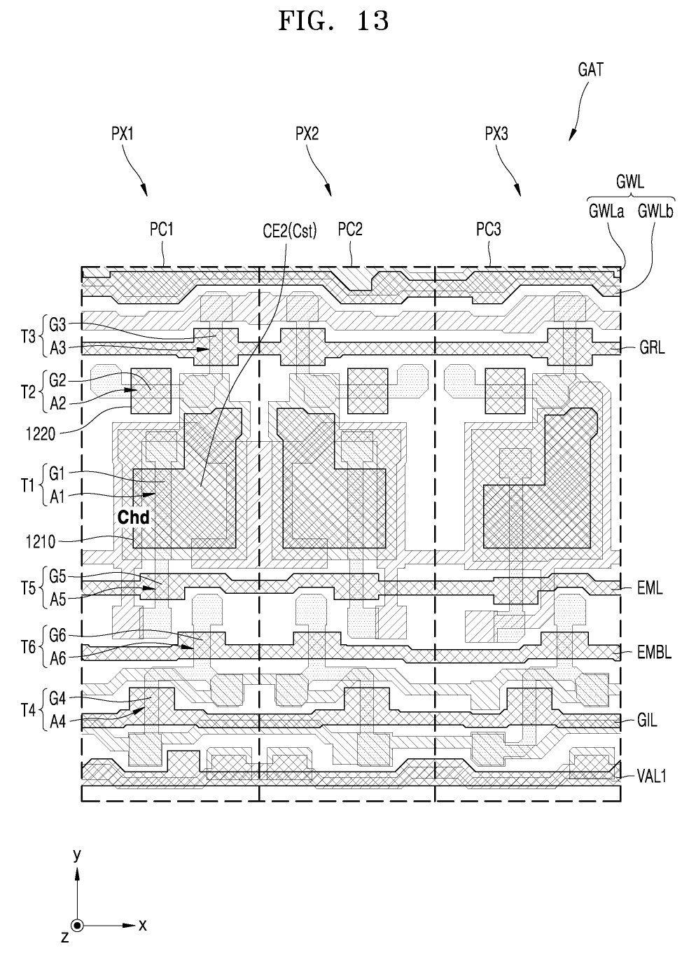

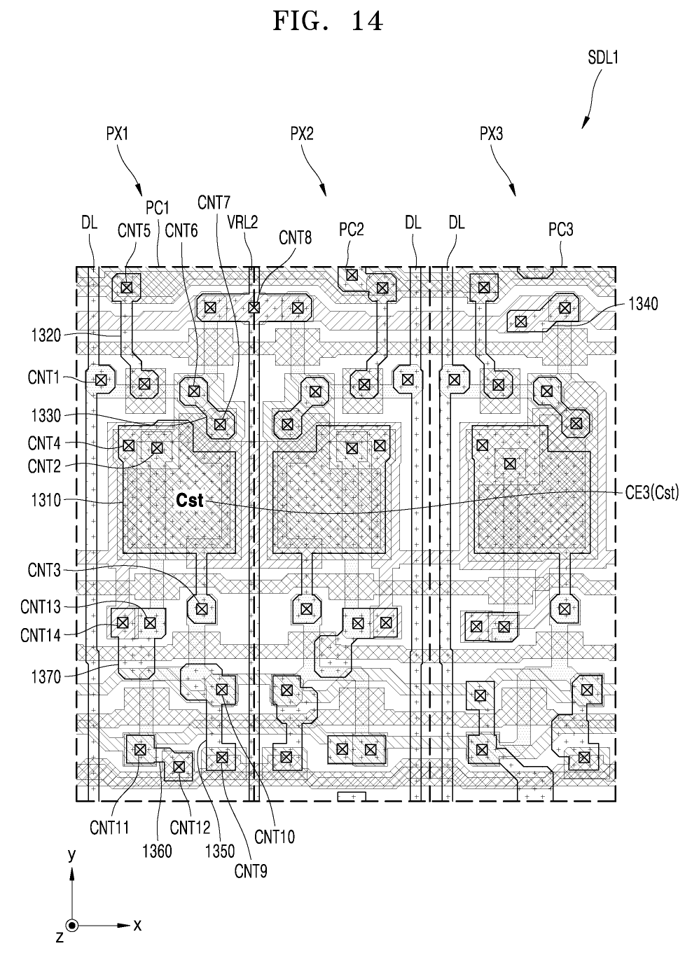

The storage capacitor Cst may be connected between the first gate electrode of the first transistor T1 and the second terminal of the first transistor T1. The storage capacitor Cst may include a first electrode CEs1 and a second electrode CEs2. The first electrode CEs1 of the storage capacitor Cst may correspond to an intermediate electrode CE2 (refer to FIG. 13) described below, and the second electrode CEs2 of the storage capacitor Cst may correspond to a lower electrode CE1 (refer to FIG. 11) and an upper electrode CE3 (refer to FIG. 14) described below.

The first electrode CEs1 of the storage capacitor Cst may be connected to the first node N1, and the second electrode CEs2 may be connected to the second node N2. The first electrode CEs1 of the storage capacitor Cst may be connected to the first gate electrode of the first transistor T1, the second terminal of the second transistor T2, and the first terminal of the third transistor T3. The second electrode CEs2 of the storage capacitor Cst may be connected to the second terminal and the 1-2 gate electrode of the first transistor T1, a second hold electrode CEh2 of the hold capacitor Chd, and the first terminal of the sixth transistor T6. The storage capacitor Cst may store a threshold voltage of the first transistor T1 and a voltage corresponding to the data signal DATA.

When the third transistor T3 and the fifth transistor T5 are turned on, the first transistor T1 may be turned on. When a voltage of the second terminal of the first transistor T1 decreases to a difference (Vref-Vth1) between the reference voltage Vref and a threshold voltage Vth1 of the first transistor T1, the first transistor T1 may be turned off, and a voltage corresponding to the threshold voltage Vth1 of the first transistor T1 may be stored in the storage capacitor Cst to compensate for the threshold voltage Vth1 of the first transistor T1.

The hold capacitor Chd may be connected between the driving voltage line PL and the second node N2. A first hold electrode CEh1 of the hold capacitor Chd may be connected to the driving voltage line PL. The second hold electrode CEh2 of the hold capacitor Chd may be connected to the second terminal and the 1-2 gate electrode of the first transistor T1, the second electrode CEs2 of the storage capacitor Cst, and the first terminal of the sixth transistor T6. The hold capacitor Chd ensures that voltages of a lower gate electrode of the first transistor T1 and the second node N2 remain constant, even when a surrounding signal changes.

The pixel circuit PC may further include an auxiliary capacitor Ca. The auxiliary capacitor Ca may be electrically connected to the sixth transistor T6, a sustain voltage line VSSL, and the pixel electrode of the light-emitting diode LED. The auxiliary capacitor Ca may store and maintain a voltage corresponding to a voltage difference between the pixel electrode of the light-emitting diode LED and the sustain voltage line VSSL, thereby preventing an increase in black luminance when the sixth transistor T6 is turned off.

The light-emitting diode LED may be connected to the first transistor T1 through the sixth transistor T6. The light-emitting diode LED may include the pixel electrode (anode) connected to the third node N3 and a counter electrode (cathode) facing the pixel electrode, and the counter electrode may receive a common voltage ELVSS. In an embodiment, the counter electrode (cathode) may extend to a display area and may be electrically connected to the sustain voltage line VSSL that provides the common voltage ELVSS. Due to the fifth transistor T5 and the sixth transistor T6 which are turned on, driving current output from the first transistor T1 may flow through the light-emitting diode LED, and the light-emitting diode LED may emit light with luminance corresponding to a magnitude of the driving current.

Although the pixel circuit PC includes six transistors in FIG. 7, the disclosure is not limited thereto. In another embodiment, the pixel circuit PC may include seven transistors. In another embodiment, the number of transistors of the pixel circuit PC may be 5 or less, or 8 or more.

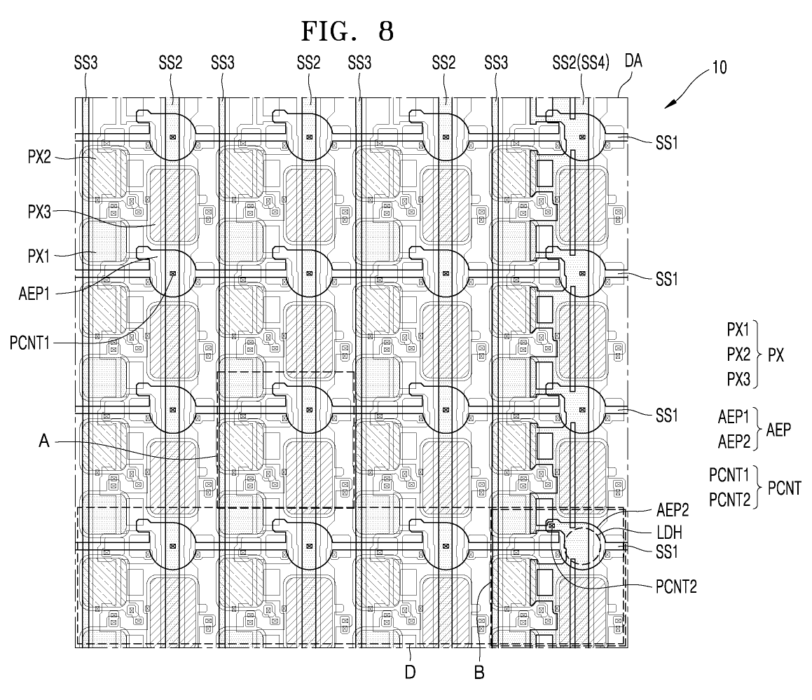

FIG. 8 is a plan view schematically illustrating an embodiment of a part of a display area of a display apparatus of the disclosure.

Referring to FIG. 8, a plurality of pixels PX may be disposed in the display area DA. Each of the plurality of pixels PX may include the pixel circuit PC and the light-emitting diode LED as described with reference to FIG. 7.

The plurality of pixels PX may include first to third pixels PX1, PX2, and PX3 arranged in rows in the first direction (e.g., the x-axis direction) and in columns in the second direction (e.g., the y-axis direction). Each of the first to third pixels PX1, PX2, and PX3 is a sub-pixel, and a unit including the first to third pixels PX1, PX2, and PX3 may function as one pixel emitting light. The first to third pixels PX1, PX2, and PX3 may emit light having different wavelengths. In an embodiment, the first pixel PX1 may emit first color light having a red wavelength, the second pixel PX2 may emit second color light having a green wavelength, and the third pixel PX3 may emit third color light having a blue wavelength, for example.

In an embodiment, the first pixel PX1 and the second pixel PX2 may be disposed in the same column, and the third pixel PX3 may be disposed in another column. The first pixel PX1 and the second pixel PX2 may be alternately disposed in a first column (e.g., a j^{th} column). The third pixel PX3 may be disposed in a second column (e.g., a j+1^{th} column) next (adjacent) to the first column (e.g., the j^{th} column) in which the first pixel PX1 and the second pixel PX2 are disposed. Also, each of the first pixel PX1, the second pixel PX2, and the third pixel PX3 may be disposed in the same row. In other words, the first pixel PX1 may be disposed in a first row (e.g., an i^{th} row), the second pixel PX2 may be disposed in a second row (e.g., an i+1^{th} row), and the third pixel PX3 may be disposed in a third row (e.g., an i+2^{th} row).

For reference, when the first to third pixels PX1, PX2, and PX3 are arranged in rows and columns as described above, it may mean positions where first to third pixel electrodes PE1, PE2, and PE3 including emission areas are arranged.

In detail, areas where the first pixel PX1, the second pixel PX2, and the third pixel PX3 of FIG. 8 are disposed may be an area (hereinafter, a first pixel circuit area) where a first pixel circuit included in the first pixel PX1 is disposed, an area (hereinafter, also referred to as a second pixel circuit area) where a second pixel circuit included in the second pixel PX2 is disposed, and an area (hereinafter, also referred to as a third pixel circuit area) where a third pixel circuit included in the third pixel PX3 is disposed. However, the light-emitting diode included in the first pixel PX1 does not have to be disposed within the first pixel circuit area. In an embodiment, as shown in FIG. 8, the first pixel electrode PE1 electrically connected to the first pixel circuit included in the first pixel PX1 may be disposed across the first pixel circuit area and may also be disposed across areas corresponding to pixels disposed in a +y direction of the first pixel PX1, for example. Also, the second pixel electrode PE2 electrically connected to the second pixel circuit included in the second pixel PX2 may be disposed in the first pixel circuit area while being disposed in a -y direction from the first pixel electrode PE1. Also, the third pixel electrode PE3 electrically connected to the third pixel circuit included in the third pixel PX3 may be disposed across the second pixel circuit area and the third pixel circuit area and may also be disposed across areas corresponding to pixels disposed in a -y direction of the pixels. In this case, in the first column (e.g., the j^{th} column), the first pixel electrodes PE1 and the second pixel electrodes PE2 may be alternately disposed; in the second column (e.g., the j+1^{th} column) next (adjacent) to the first column (e.g., the j^{th} column), the third pixel electrodes PE3 may be disposed; and the two columns may be alternately disposed along the first direction (e.g., the x-axis direction).

FIG. 8 illustrates a structure in which pixel units each including the first to third pixels PX1, PX2, and PX3 are arranged in a 4X4 array. In the display apparatus 10 in an embodiment of the disclosure, the 4X4 pixel arrangement structure of FIG. 8 may be repeatedly provided in the display area DA, or a structure including the 4X4 pixel arrangement structure of FIG. 8 may be repeatedly provided in the display area DA.

In an embodiment, in the display area DA, a first common voltage line SS1 extending in the first direction (e.g., the x-axis direction), and a second common voltage line SS2 and a third common voltage line SS3 extending in the second direction (e.g., the y-axis direction) may be disposed.

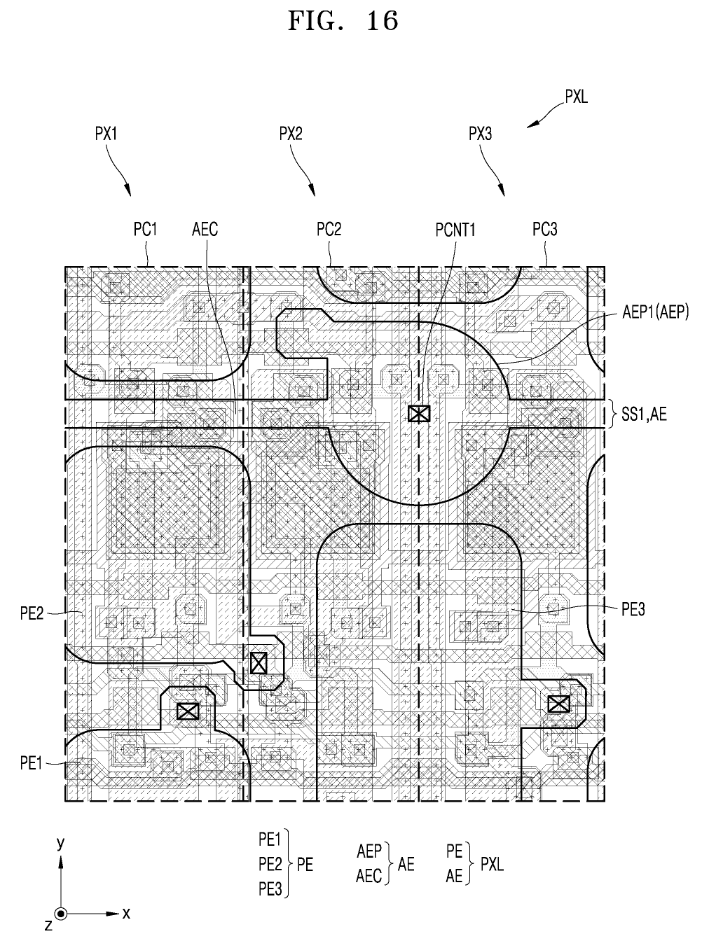

The first common voltage line SS1 may extend in the first direction (e.g., the x-axis direction) across the entirety of the display area DA. The first common voltage lines SS1 may be spaced apart from each other by a predetermined interval in the second direction (e.g., the y-axis direction) in the display area DA. The first common voltage line SS1 may be also referred to as an auxiliary electrode AE described below with reference to FIG. 16.

The first common voltage line SS1 may include a plurality of pad units AEP spaced apart from each other by a predetermined interval. Each of the plurality of pad units AEP of the first common voltage line SS1 may be disposed between the third pixel electrodes PE3 of the third pixel PX3 arranged in the second direction (e.g., the y-axis direction). That is, the pad unit AEP and the third pixel electrode PE3 may be alternately disposed along the second direction (e.g., the y-axis direction).

The second common voltage line SS2 and the third common voltage line SS3 may extend in the second direction (e.g., the y-axis direction) across the entirety of the display area DA. The second common voltage line SS2 and the third common voltage line SS3 may be disposed in a different layer from the first common voltage line SS1. The second common voltage line SS2 and the third common voltage line SS3 may be disposed under the first common voltage line in a cross-sectional view. In an embodiment, the first common voltage line SS1 may be disposed in the same layer as the first pixel electrode PE1, and the second common voltage line SS2 and the third common voltage line SS3 may be disposed under the first pixel electrode PE1, for example. That is, the second common voltage line SS2 and the third common voltage line SS3 may be disposed between the first common voltage line SS1 and the substrate 100 in a cross-sectional view.

The second common voltage line SS2 may be disposed to overlap the plurality of pad units AEP of the first common voltage line SS1. In other words, the second common voltage line SS2 may be disposed along the second direction (e.g., the y-axis direction), and the plurality of pad units AEP of the first common voltage line SS1 may be disposed over the second common voltage line SS2. Accordingly, the second common voltage line SS2 may be electrically connected to the plurality of pad units AEP of the first common voltage line SS1 through contact portions PCNT, to form a substantially mesh structure in the display area DA. Through this structure, in the display apparatus 10 including the relatively large display area DA, voltage drop in the driving voltage line PL (refer to FIG. 7) may be prevented or minimized.

The plurality of pad units AEP may include a first pad unit AEP1 and a second pad unit AEP2. The first pad unit AEP1 and the second pad unit AEP2 have substantially the same shape, but are different in a position of the contact portion PCNT contacting the second common voltage line SS2. In more detail, the first pad unit AEP1 may include a first contact portion PCNT1 contacting the second common voltage line SS2, and the second pad unit AEP2 may include a second contact portion PCNT2 contacting the second common voltage line SS2. The first contact portion PCNT1 of the first pad unit AEP1 contacting the second common voltage line SS2 may be disposed at a central portion of the first pad unit AEP1. The second contact portion PCNT2 of the second pad unit AEP2 contacting the second common voltage line SS2 may be biased to one side, rather than a central portion of the second pad unit AEP2.

In FIG. 8, among the plurality of pad units APE disposed in the same area, the number of first pad units AEP1 may be greater than the number of second pad units AEP2. In an embodiment, among the plurality of pad units AEP having the 4X4 structure as shown in FIG. 8, one second pad unit AEP2 may be provided at a lower right corner, and the rest may be the first pad units AEP1, for example. However, it will be understood that the number of second pad units AEP2 among the plurality of pad units AEP may be changed as desired.

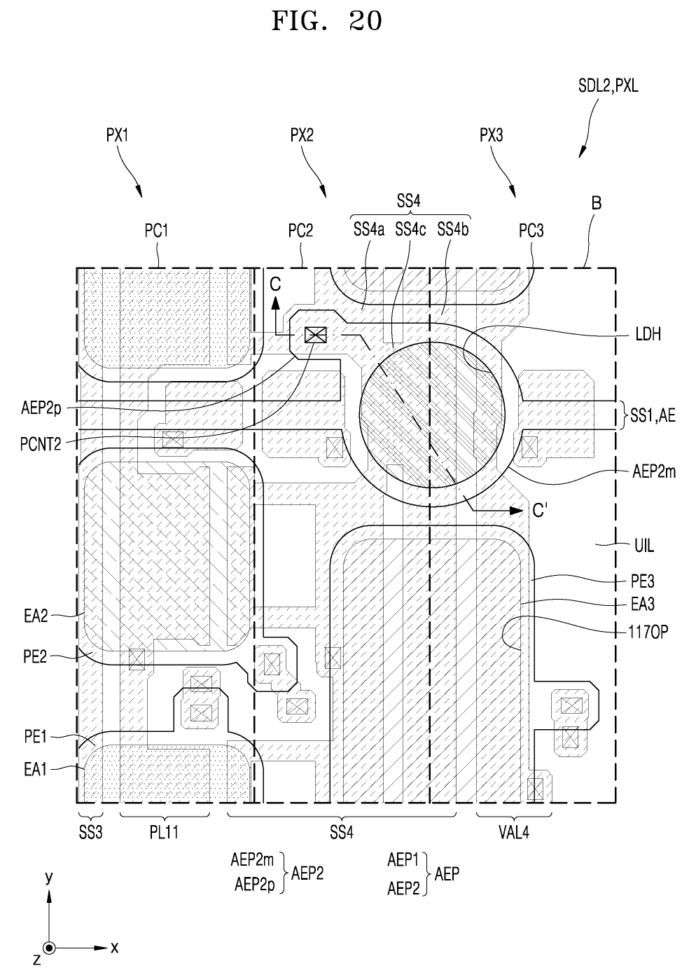

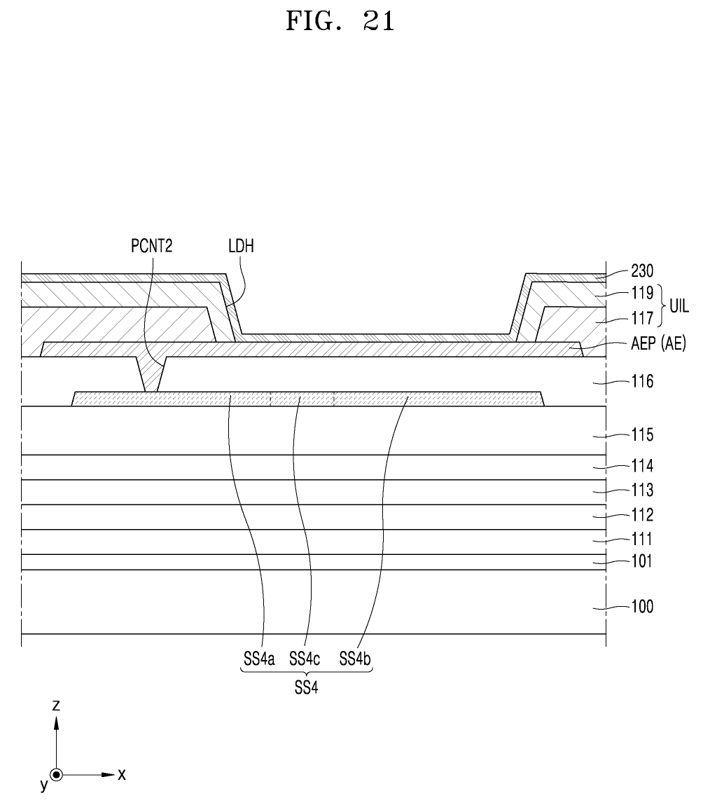

The reason that the contact portions PCNT of the first pad unit AEP1 and the second pad unit AEP2 are provided at different positions is that the second pad unit AEP2 among the plurality of pad units AEP is used as a pad for a laser drilling process. Accordingly, in order not to overlap a laser drilling opening LDH defined at a central portion of the second pad unit AEP2, the second contact portion PCNT2 of the second pad unit AEP2 may be biased to one side, rather than the central portion of the second pad unit AEP2. This will be described below in detail with reference to FIGS. 20 and 21.

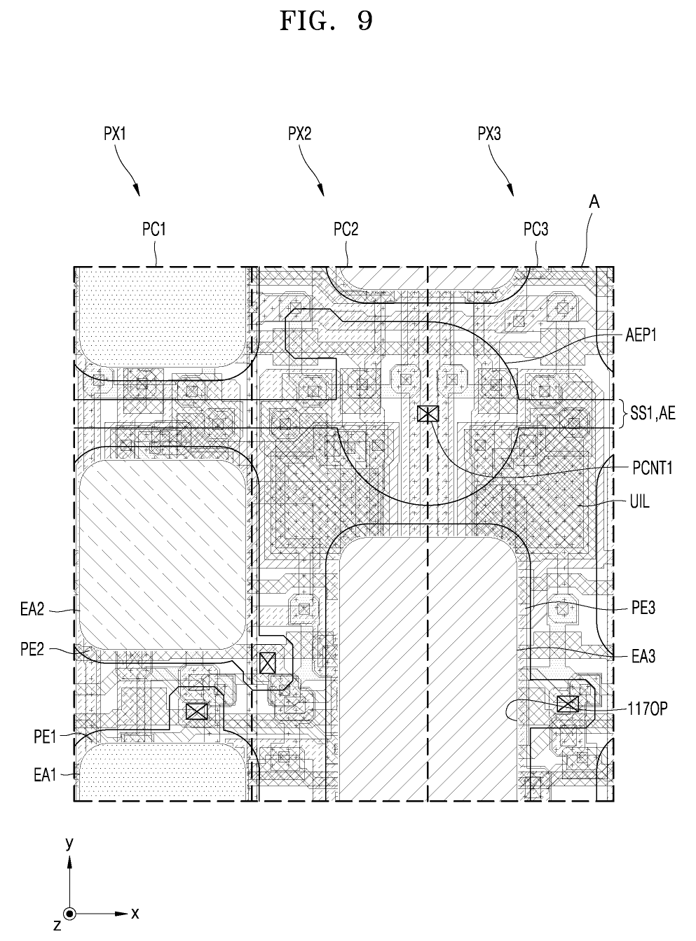

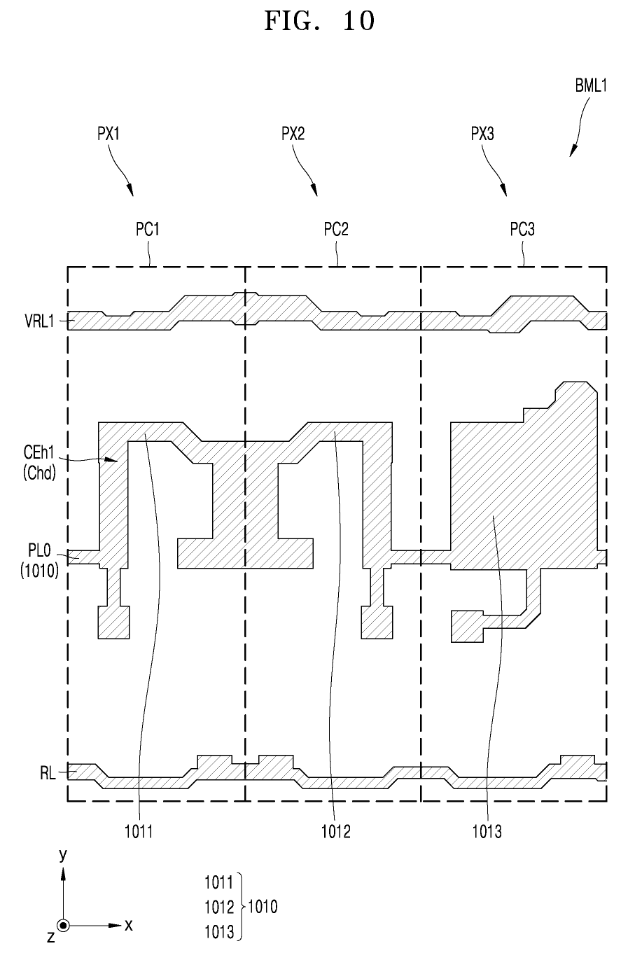

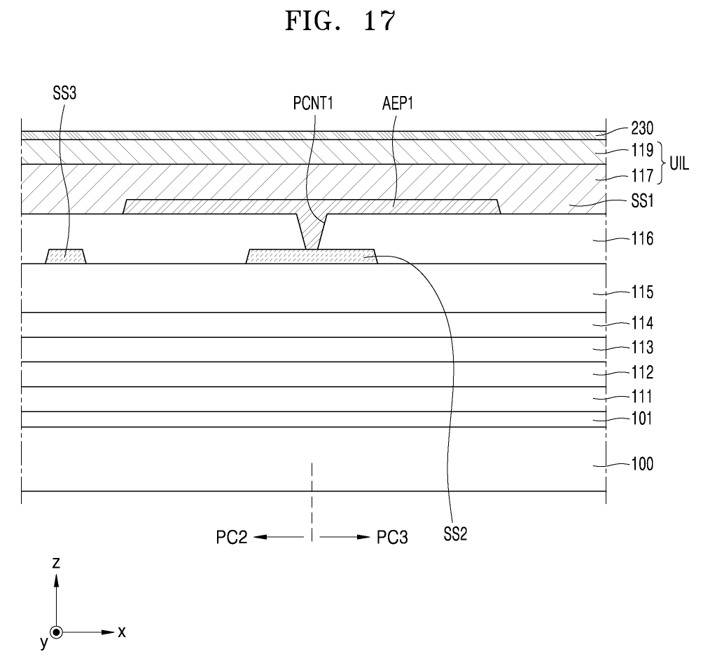

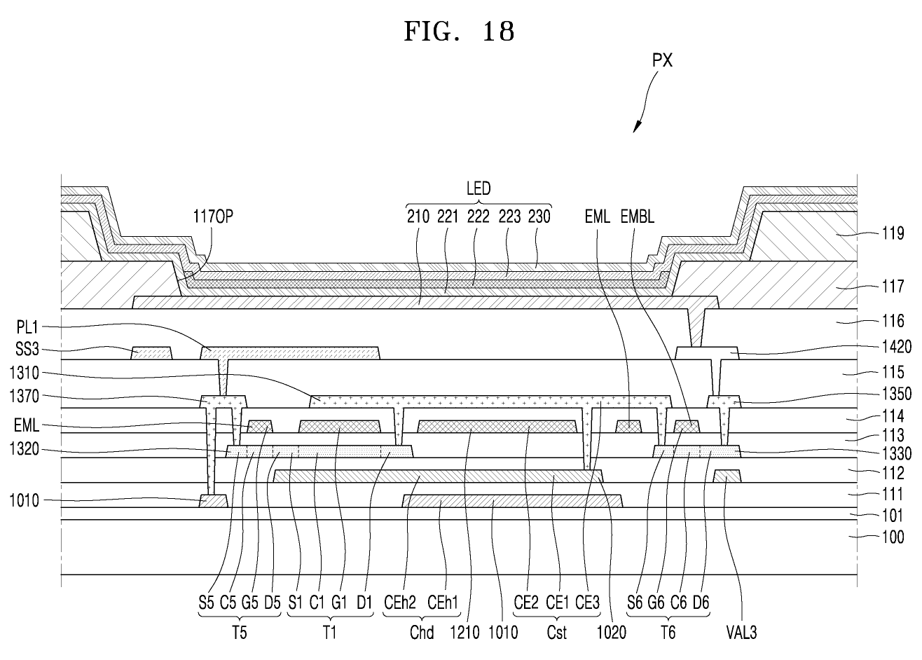

FIG. 9 is a layout diagram schematically illustrating an embodiment of a structure of pixel circuits in pixels of the disclosure, and FIG. 9 may correspond to an enlarged structure illustrating a portion A of FIG. 8. FIGS. 10 to 16 are layout diagrams illustrating conductive patterns constituting the pixel circuit of FIG. 9, according to respective layers. FIG. 17 is a cross-sectional view schematically illustrating an embodiment of a cross-section including a pad unit of the disclosure. FIG. 18 is a cross-sectional view schematically illustrating an embodiment of a part of a structure of a pixel circuit of the disclosure.

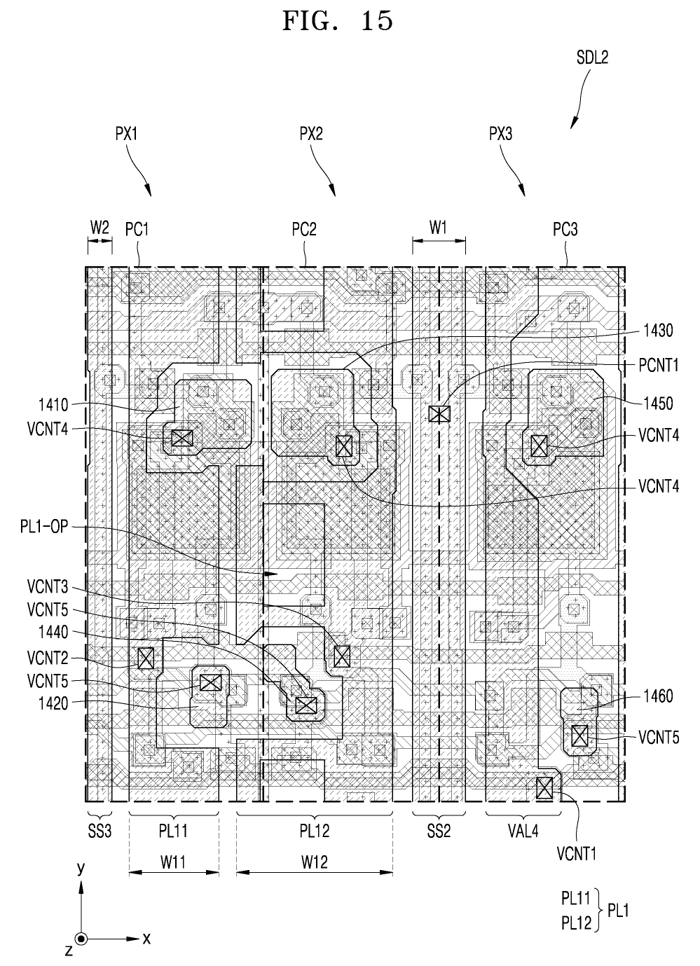

FIG. 9 is a layout diagram schematically illustrating an embodiment of positions of a plurality of transistors (e.g., T1, T2, T3, T4, T5, and T6) and a plurality of capacitors (e.g., Cst, Chd, and Ca) in the pixels PX included in the display apparatus 10 of the disclosure, FIGS. 10 to 15 are layout diagrams schematically illustrating layers of components such as the plurality of transistors (e.g., T1, T2, T3, T4, T5, and T6) and the plurality of capacitors (e.g., Cst, Chd, and Ca) of FIG. 9, FIG. 16 is a layout diagram schematically illustrating the first to third pixel electrodes PE1, PE2, and PE3 that may be electrically connected to the pixel circuits of FIG. 15, and FIG. 18 is a cross-sectional view schematically illustrating a partial cross-section of FIG. 9. In the cross-sectional views, a size of each component may be exaggerated and/or reduced for convenience.

Referring to FIGS. 10 to 16 together with FIG. 9, the display apparatus 10 may have a structure in which a set of first to third pixels PX1, PX2, and PX3 is repeatedly disposed in the first direction (e.g., the x-axis direction). Such a set of first to third pixels PX1, PX2, and PX3 may also be repeatedly disposed in the second direction (e.g., the y-axis direction). The set of first to third pixels PX1, PX2, and PX3 may be repeatedly disposed in the first direction (e.g., the x-axis direction) and/or the second direction (e.g., the y-axis direction) as shown in FIG. 9, or an extended set including the first to third pixels PX1, PX2, and PX3 may be repeatedly disposed.

For reference, areas where the first to third pixels PX1, PX2, and PX3 of FIGS. 9 and 10 to 16 are disposed may be areas where a first pixel circuit PC1 included in the first pixel PX1, a second pixel circuit PC2 included in the second pixel PX2, and a third pixel circuit PC3 included in the third pixel PX3 are disposed. The first pixel circuit PC1 of the first pixel PX1 may be also referred to as a first color pixel circuit, the second pixel circuit PC2 of the second pixel PX2 may be also referred to as a second color pixel circuit, and the third pixel circuit PC3 of the third pixel PX3 may be also referred to as a third color pixel circuit. In an embodiment, a first color may be red, a second color may be green, and a third color may be blue, for example.

However, a light-emitting diode included in the first pixel PX1 does not have to be disposed in an area corresponding to the first pixel PX1. In an embodiment, as shown in FIGS. 9 and 16, the first pixel electrode PE1 included in the first pixel PX1 may be disposed across an area corresponding to the first pixel circuit PC1 and may extend in the -y direction, the second pixel electrode PE2 included in the second pixel PX2 may be disposed in the +y direction from the first pixel electrode PE1 and disposed in an area corresponding to the first pixel circuit PC1, and the third pixel electrode PE3 included in the third pixel PX3 may be disposed across an area corresponding to the second pixel circuit PC2 and an area corresponding to the third pixel circuit PC3 and extend in the -y direction, for example. In this case, in one column, the first pixel electrodes PE1 and the second pixel electrodes PE2 may be alternately disposed; in another column, the third pixel electrodes PE3 may be disposed, and the two columns may be alternately disposed along the first direction (e.g., the x-axis direction). As such, areas where the first pixel electrode to the third pixel electrode PE1, PE2, and PE3 are disposed may correspond to areas where first to third emission areas EA1, EA2, and EA3 of the first to third pixels PX1, PX2, and PX3 are disposed.

The first pixel circuit PC1 and the second pixel circuit PC2 described below with reference to FIGS. 9 to 16 may be substantially symmetrical to each other with respect to a boundary between the first pixel circuit PC1 and the second pixel circuit PC2. The third pixel PX3 may be provided in a shape separate from the second pixel PX2. In another embodiment, the second pixel PX2 and the third pixel PX3 may be substantially symmetrical to each other with respect to a boundary between the second pixel PX2 and the third pixel PX3.

Referring to FIGS. 10 and 18 together, the substrate 100 may include a glass material, a ceramic material, a metal material, plastic, or a flexible or bendable material. When the substrate 100 is flexible or bendable, the substrate 100 may include a polymer resin such as polyethersulfone (“PES”), polyacrylate, polyetherimide (“PEI”), polyethylene naphthalate (“PEN”), polyethylene terephthalate (“PET”), polyphenylene sulfide (“PPS”), polyarylate, polyimide (“PI”), polycarbonate, or cellulose acetate propionate (“CAP”). The substrate 100 may have a single or multi-layer structure including the above material, and when the substrate 100 has a multi-layer structure, the substrate 100 may further include an inorganic layer. In an embodiment, the substrate 100 may have a structure in which a layer including the above polymer resin and a barrier layer including an inorganic insulating material are alternately stacked, for example.

A buffer layer 101 may be disposed on the substrate 100. The buffer layer 101 may include silicon oxide, silicon nitride, or silicon oxynitride. The buffer layer 101 may prevent metal atoms or impurities from being diffused from the substrate 100 into a semiconductor layer ACT disposed thereon. Also, the buffer layer 101 may adjust a heat supply rate during a crystallization process for forming the semiconductor layer ACT so that the semiconductor layer ACT is uniformly crystalized.

A first bottom metal layer BML1 may be disposed on the buffer layer 101. The first bottom metal layer BML1 may include a lower conductive pattern 1010, a first reference voltage line VRL1, and a repair line RL. Each of the lower conductive pattern 1010, the first reference voltage line VRL1, and the repair line RL may extend substantially in the first direction (e.g., the x-axis direction).

The first bottom metal layer BML1 may include a metallic material. In detail, the first bottom metal layer BML1 may include at least one material selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, the first bottom metal layer BML1 may have a single-layer structure including molybdenum, may have a two-layer structure in which a molybdenum layer and a titanium layer are stacked, or may have a three-layer structure in which a titanium layer, an aluminum layer, and a titanium layer are stacked, for example.

The lower conductive pattern 1010 may have a constant voltage level. In other words, the lower conductive pattern 1010 may be also referred to as a lower driving voltage line PL0. In an embodiment, the lower driving voltage line PL0 may have the same voltage level as the driving voltage line PL (refer to FIG. 7). The lower driving voltage line PL0 may be electrically connected to a first upper driving voltage line PL11 and a second upper driving voltage line PL12 described below with reference to FIG. 15, to be provided as the driving voltage line PL (refer to FIG. 7) so that the driving voltage ELVDD is applied, for example. To this end, the driving voltage line PL (refer to FIG. 7) including the lower driving voltage line PL0 may be electrically connected to the driving voltage supply line 20 in the peripheral area PA as shown in FIG. 6.

The lower conductive pattern 1010 may have a shape that is symmetrical along a virtual line extending in the second direction (e.g., the y-axis direction) and disposed at a boundary between the first pixel circuit PC1 and the second pixel circuit PC2. The lower conductive pattern 1010 may include the first hold electrode CEh1 of the hold capacitor Chd. In an embodiment, the lower conductive pattern 1010 may include the first hold electrode CEh1 of the hold capacitor Chd of each of the first to third pixels PX1, PX2, and PX3, and the first hold electrodes CEh1 of the hold capacitors Chd of the first to third pixels PX1, PX2, and PX3 may be integrally connected to each other, for example.

The lower conductive pattern 1010 may include a first portion 1011 disposed to correspond to the first pixel circuit PC1, a second portion 1012 disposed to correspond to the second pixel circuit PC2, and a third portion 1013 disposed to correspond to the third pixel circuit PC3. Each of the first portion 1011, the second portion 1012, and the third portion 1013 may partially overlap a first conductive pattern 1020 (refer to FIG. 11) described below. A portion of each of the first portion 1011, the second portion 1012, and the third portion 1013 overlapping the first conductive pattern 1020 (refer to FIG. 11) in a plan view may be the first hold electrode CEh1 of the hold capacitor Chd (refer to FIG. 11).

Each of the first portion 1011 and the second portion 1012 of the lower conductive pattern 1010 may have a loop shape with an open bottom or a quadrangular frame shape with an open bottom. The first portion 1011 and the second portion 1012 may be symmetrical to each other with respect to a virtual line forming a boundary between the first pixel circuit PC1 and the second pixel circuit PC2, and the first portion 1011 and the second portion 1012 may be integrally formed (or unitary) with each other. The third portion 1013 may have a quadrangular shape with a protruding portion at an upper right side.

As each of the first portion 1011 and the second portion 1012 of the lower conductive pattern 1010 has a shape with an open bottom, a portion overlapping the data line DL may be reduced. That is, through a structure of the first portion 1011 and the second portion 1012 of the lower conductive pattern 1010, a structure separately shielding the data line DL may not be provided. Accordingly, capacitance between the data line DL and the lower conductive pattern 1010 may be reduced, and crosstalk generated in neighboring (adjacent) pixels due to coupling between the data line DL and the lower conductive pattern 1010 may be prevented.

The repair line RL may be disposed at one side of the lower conductive pattern 1010. The repair line RL may be a spare line that may be used when a defect occurs in a signal line or a voltage line included in the first to third pixel circuits PC1, PC2, and PC3 of the first to third pixels PX1, PX2, and PX3. The repair line RL may extend along the first direction (e.g., the x-axis direction) to pass through the first to third pixel circuits PC1, PC2, and PC3. That is, the repair line RL may pass through pixel circuits arranged in the same row as the first to third pixel circuits PC1, PC2, and PC3. When a pixel circuit is defective, the repair line RL may separate the light-emitting diode LED from the defective pixel circuit and may connect the light-emitting diode LED to a dummy circuit through the repair line RL. As the dummy circuit generates driving current corresponding to a data signal and supplies the driving current to the light-emitting diode LED through the repair line RL, the light-emitting diode LED may operate normally.

The first reference voltage line VRL1 may be disposed at an opposite side of the lower conductive pattern 1010. The first reference voltage line VRL1 may be a horizontal reference voltage line extending substantially in the first direction (e.g., the x-axis direction). The first reference voltage line VRL1 may be electrically connected to a second reference voltage line VRL2, which is a vertical reference voltage line described with reference to FIG. 14, and a fourth connection pattern 1340 to transmit a reference voltage to each pixel circuit.

Referring to FIGS. 11 and 18 together, a first insulating layer 111 may be disposed on the first bottom metal layer BML1, and a second bottom metal layer BML2 may be disposed on the first insulating layer 111. The second bottom metal layer BML2 may include the first conductive pattern 1020, a second conductive pattern 1030, a first write gate line GWLa, a second initialization voltage line VAL2, and a third initialization voltage line VAL3.

The first insulating layer 111 may include an inorganic insulating material. The first insulating layer 111 may include silicon oxide, silicon nitride, silicon oxynitride, or aluminum oxide, for example.

The second bottom metal layer BML2 may include a metallic material. In detail, the second bottom metal layer BML2 may include at least one material selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, the second bottom metal layer BML2 may have a single-layer structure including molybdenum, may have a two-layer structure in which a molybdenum layer and a titanium layer are stacked, or may have a three-layer structure in which a titanium layer, an aluminum layer, and a titanium layer are stacked, for example.

The first conductive pattern 1020 may have an isolated shape. The first conductive pattern 1020 may be disposed to correspond to each of the first pixel circuit PC1, the second pixel circuit PC2, and the third pixel circuit PC3. Each first conductive pattern 1020 may have a shape symmetrical along a virtual line extending in the second direction (e.g., the y-axis direction) at a boundary between the first pixel circuit PC1 and the second pixel circuit PC2. The first conductive pattern 1020 may be disposed to overlap at least a part of the first bottom metal layer BML1 described with reference to FIG. 10. In detail, the first conductive pattern 1020 may at least partially overlap the lower conductive pattern 1010 described with reference to FIG. 10.

The first conductive pattern 1020 may include the second hold electrode CEh2 of the hold capacitor Chd. The first hold electrode CEh1 of the hold capacitor Chd described with reference to FIG. 10 may overlap the second hold electrode CEh2 of the hold capacitor Chd to constitute the hold capacitor Chd.

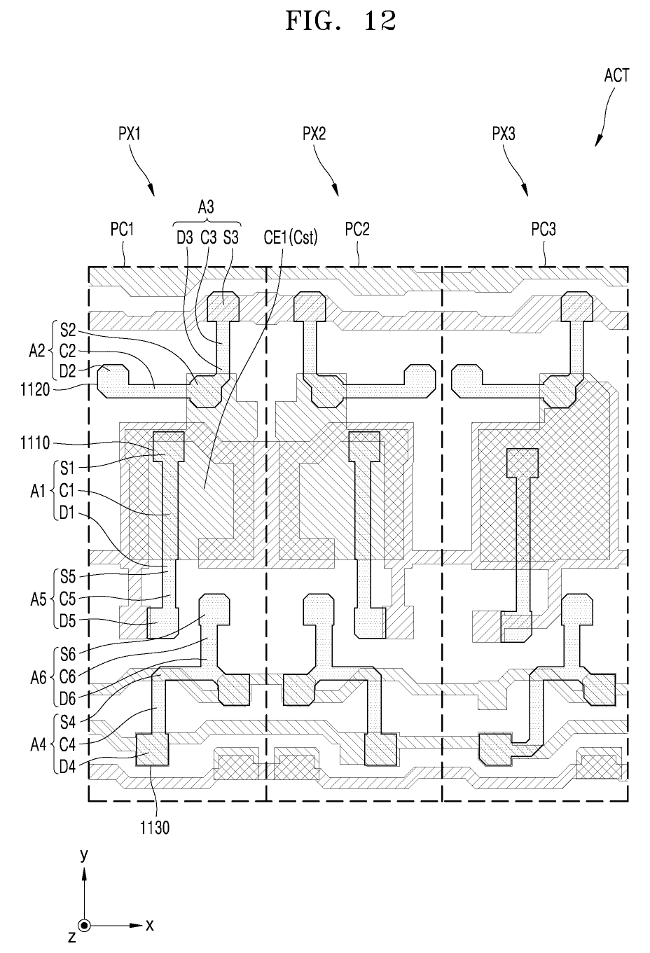

The first conductive pattern 1020 may include the lower electrode CE1 of the storage capacitor Cst. In an embodiment, the first conductive pattern 1020 may include a lower gate electrode (e.g., a 1-2 gate electrode) of the first transistor T1 (refer to FIG. 13) overlapping a first semiconductor layer A1 (refer to FIG. 13) of the first transistor T1 (refer to FIG. 12). The second hold electrode CEh2 of the hold capacitor Chd and the lower electrode CE1 of the storage capacitor Cst may be integrally formed (or unitary), and may be connected to the second node N2 described with reference to FIG. 7.

The first write gate line GWLa, the second initialization voltage line VAL2, and the third initialization voltage line VAL3 may extend in the first direction (e.g., the x-axis direction) to respectively pass through areas corresponding to the first pixel circuit PC1, the second pixel circuit PC2, and the third pixel circuit PC3.

The first write gate line GWLa may be disposed at one side of the first conductive pattern 1020, and the second initialization voltage line VAL2 and the third initialization voltage line VAL3 may be disposed at an opposite side of the first conductive pattern 1020. In an embodiment, in a plan view of FIG. 11, the first write gate line GWLa may be disposed above the first conductive pattern 1020, and the second initialization voltage line VAL2 and the third initialization voltage line VAL3 may be disposed below the first conductive pattern 1020, for example. In an embodiment, the first conductive pattern 1020 may be disposed between the first write gate line GWLa and the third initialization voltage line VAL3, for example.

The second conductive pattern 1030 may be disposed opposite to the third initialization voltage line VAL3 with respect to the second initialization voltage line VAL2. The second conductive pattern 1030 may have an isolated shape. The second conductive pattern 1030 may be disposed to overlap the repair line RL described with reference to FIG. 10, and may be a repair pattern that is electrically connected to the repair line RL when a defect occurs in a signal line or a voltage line.

Referring to FIGS. 12 and 18 together, a second insulating layer 112 may be disposed on the second bottom metal layer BML2, and the semiconductor layer ACT may be disposed on the second insulating layer 112. The semiconductor layer ACT may include a first semiconductor pattern 1110, a second semiconductor pattern 1120, and a third semiconductor pattern 1130.

The second insulating layer 112 may include an inorganic insulating material. The second insulating layer 112 may include silicon oxide, silicon nitride, silicon oxynitride, or aluminum oxide, for example.

The semiconductor layer ACT may include an oxide semiconductor material. That is, the first to third semiconductor patterns 1110, 1120, and 1130 may include the same material as each other. In an embodiment, each of the first to third semiconductor patterns 1110, 1120, and 1130 may include at least one oxide semiconductor material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In another embodiment, the first to third semiconductor patterns 1110, 1120, and 1130 may include polysilicon or amorphous silicon.

Each of the first semiconductor pattern 1110, the second semiconductor pattern 1120, and the third semiconductor pattern 1130 may have an isolated shape. In an embodiment, the first semiconductor pattern 1110, the second semiconductor pattern 1120, and the third semiconductor pattern 1130 may be spaced apart from each other, for example. Each of the first semiconductor pattern 1110, the second semiconductor pattern 1120, and the third semiconductor pattern 1130 may be disposed to correspond to each of the first pixel circuit PC1, the second pixel circuit PC2, and the third pixel circuit PC3.

The first semiconductor pattern 1110 may include the first semiconductor layer A1 and a fifth semiconductor layer A5. In other words, the first semiconductor layer A1 and the fifth semiconductor layer A5 may be integrally connected to each other. The second semiconductor pattern 1120 may include a second semiconductor layer A2 and a third semiconductor layer A3. In other words, the second semiconductor layer A2 and the third semiconductor layer A3 may be integrally connected to each other. The third semiconductor pattern 1130 may include a fourth semiconductor layer A4 and a sixth semiconductor layer A6. In other words, the fourth semiconductor layer A4 and the sixth semiconductor layer A6 may be integrally connected to each other.

The first semiconductor pattern 1110 may be disposed in each of the first pixel circuit PC1, the second pixel circuit PC2, and the third pixel circuit PC3. The first semiconductor pattern 1110 may have a shape extending in the second direction (e.g., the y-axis direction). In an embodiment, the first semiconductor pattern 1110 may have an ‘I’ shape, for example. The first semiconductor pattern 1110 may include the first semiconductor layer A1 of the first transistor T1 (refer to FIG. 13) and the fifth semiconductor layer A5 of the fifth transistor T5 (refer to FIG. 13). The first semiconductor layer A1 and the fifth semiconductor layer A5 may be integrally connected to each other.

The first semiconductor layer A1 may include a first channel region C1 overlapping a first gate electrode G1 of the first transistor T1 described below with reference to FIG. 13, a first source region S1 disposed on one side of the first channel region C1, and a first drain region D1 disposed on an opposite side of the first channel region C1.

The second semiconductor layer A2 may include a second channel region C2 overlapping a second gate electrode G2 of the second transistor T2 described below with reference to FIG. 13, a second source region S2 disposed on one side of the second channel region C2, and a second drain region D2 disposed on an opposite side of the second channel region C2.

The second semiconductor pattern 1120 may be disposed in each of the first pixel circuit PC1, the second pixel circuit PC2, and the third pixel circuit PC3. The second semiconductor pattern 1120 may have a bent shape. In an embodiment, the second semiconductor pattern 1120 may have an ‘L’ shape or an inverted ‘L’ shape, for example. The second semiconductor pattern 1120 may include the second semiconductor layer A2 of the second transistor T2 (refer to FIG. 13) and the third semiconductor layer A3 of the third transistor T3 (refer to FIG. 13). The second semiconductor layer A2 and the third semiconductor layer A3 may be integrally connected to each other.

The third semiconductor layer A3 may include a third channel region C3 overlapping a third gate electrode G3 of the third transistor T3 described below with reference to FIG. 13, a third source region S3 disposed on one side of the third channel region C3, and a third drain region D3 disposed on an opposite side of the third channel region C3.

The fourth semiconductor layer A4 may include a fourth channel region C4 overlapping a fourth gate electrode G4 of the fourth transistor T4 described below with reference to FIG. 13, a fourth source region S4 disposed on one side of the fourth channel region C4, and a fourth drain region D4 disposed on an opposite side of the fourth channel region C4.

The third semiconductor pattern 1130 may be disposed in each of the first pixel circuit PC1, the second pixel circuit PC2, and the third pixel circuit PC3. The third semiconductor pattern 1130 may have a shape that is bent several times. The third semiconductor pattern 1130 may include the fourth semiconductor layer A4 of the fourth transistor T4 (refer to FIG. 13) and the sixth semiconductor layer A6 of the sixth transistor T6 (refer to FIG. 13). The fourth semiconductor layer A4 and the sixth semiconductor layer A6 may be integrally connected to each other.

The fifth semiconductor layer A5 may include a fifth channel region C5 overlapping a fifth gate electrode G5 of the fifth transistor T5 described below with reference to FIG. 13, a fifth source region S5 disposed on one side of the fifth channel region C5, and a fifth drain region D5 disposed on an opposite side of the fifth channel region C5.

The sixth semiconductor layer A6 may include a sixth channel region C6 overlapping a sixth gate electrode G6 of the sixth transistor T6 described below with reference to FIG. 13, a sixth source region S6 disposed on one side of the sixth channel region C6, and a sixth drain region D6 disposed on an opposite side of the sixth channel region C6.

Referring to FIGS. 13 and 18, a third insulating layer 113 may be disposed on the semiconductor layer ACT, and a gate layer GAT may be disposed on the third insulating layer 113. The gate layer GAT may include a third conductive pattern 1210, a fourth conductive pattern 1220, a second write gate line GWLb, the reference gate line GRL, the first emission control line EML, the second emission control line EMBL, the initialization gate line GIL, and a first initialization voltage line VAL1.

The third insulating layer 113 may include an inorganic insulating material. The third insulating layer 113 may include silicon oxide, silicon nitride, silicon oxynitride, or aluminum oxide, for example.

The gate layer GAT may include a metal, an alloy, a conductive metal oxide, or a transparent conductive material. In an embodiment, the gate layer GAT may include silver (Ag), an alloy including or consisting of silver, molybdenum (Mo), an alloy including or consisting of molybdenum, aluminum (Al), an alloy including or consisting of aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), or indium zinc oxide (“IZO”), for example. The gate layer GAT may have a multi-layer structure, and for example, the gate layer GAT may have a two-layer structure including Mo/Al or a three-layer structure including Mo/Al/Mo.

Each of the third conductive pattern 1210 and the fourth conductive pattern 1220 may have an isolated shape. In an embodiment, the third conductive pattern 1210 and the fourth conductive pattern 1220 may be spaced apart from each other, for example. Each of the third conductive pattern 1210 and the fourth conductive pattern 1220 may be disposed to correspond to each of the first pixel circuit PC1, the second pixel circuit PC2, and the third pixel circuit PC3.

The third conductive pattern 1210 may overlap at least a part of the first semiconductor pattern 1110. The third conductive pattern 1210 may include the first gate electrode G1 of the first transistor T1 overlapping the first semiconductor layer A1 of the first transistor T1. The first gate electrode G1 may be an upper gate electrode (e.g., 1-1 gate electrode).

The third conductive pattern 1210 may include the intermediate electrode CE2 of the storage capacitor Cst connected to the first node N1 described with reference to FIG. 7. The third conductive pattern 1210 may partially overlap the first conductive pattern 1020 (refer to FIG. 11) disposed under the third conductive pattern 1210. A portion of the third conductive pattern 1210 overlapping the first conductive pattern 1020 (refer to FIG. 11) in a plan view may be the intermediate electrode CE2 of the storage capacitor Cst. The intermediate electrode CE2 of the storage capacitor Cst may overlap the lower electrode CE1 (refer to FIG. 12) and the upper electrode CE3 (refer to FIG. 14) of the storage capacitor Cst to constitute the storage capacitor Cst. The first gate electrode G1 of the first transistor T1 and the intermediate electrode CE2 of the storage capacitor Cst may be integrally formed (or unitary).

The fourth conductive pattern 1220 may overlap at least a part of the second semiconductor pattern 1120. The fourth conductive pattern 1220 may include the second gate electrode G2 of the second transistor T2 overlapping the second semiconductor layer A2 of the second transistor T2.

Each of the second write gate line GWLb, the reference gate line GRL, the first emission control line EML, the initialization gate line GIL, the second emission control line EMBL, and the first initialization voltage line VAL1 may extend substantially in the first direction (e.g., the x-axis direction) to pass through the first pixel circuit PC1, the second pixel circuit PC2, and the third pixel circuit PC3.

In a plan view, each of the second write gate line GWLb and the reference gate line GRL may be disposed at one side of the third conductive pattern 1210, and the first emission control line EML, the initialization gate line GIL, the second emission control line EMBL, and the first initialization voltage line VAL1 may be disposed at an opposite side of the third conductive pattern 1210. In an embodiment, in a plan view of FIG. 13, each of the second write gate line GWLb and the reference gate line GRL may be disposed above the third conductive pattern 1210, and each of the first emission control line EML, the initialization gate line GIL, the second emission control line EMBL, and the first initialization voltage line VAL1 may be disposed below the third conductive pattern 1210, for example.

The second write gate line GWLb may be disposed on the first write gate line GWLa to at least partially overlap the first write gate line GWLa. That is, the write gate line GWL may include the first write gate line GWLa and the second write gate line GWLb disposed in different layers.

The reference gate line GRL may overlap at least a part of the second semiconductor pattern 1120. The reference gate line GRL may include the third gate electrode G3 of the third transistor T3 overlapping the third semiconductor layer A3 of the third transistor T3.

The first emission control line EML may overlap at least a part of the first semiconductor pattern 1110. The first emission control line EML may include the fifth gate electrode G5 of the fifth transistor T5 overlapping the fifth semiconductor layer A5 of the fifth transistor T5.

The initialization gate line GIL may overlap at least a part of the third semiconductor pattern 1130. The initialization gate line GIL may include the fourth gate electrode G4 of the fourth transistor T4 overlapping the fourth semiconductor layer A4 of the fourth transistor T4.

The second emission control line EMBL may overlap at least a part of the third semiconductor pattern 1130. The second emission control line EMBL may include the sixth gate electrode G6 of the sixth transistor T6 overlapping the sixth semiconductor layer A6 of the sixth transistor T6.

Referring to FIGS. 14 and 18 together, a fourth insulating layer 114 may be disposed on the gate layer GAT, and a first source-drain layer SDL1 may be disposed on the fourth insulating layer 114. The first source-drain layer (also referred to as a first conductive layer) SDL1 may include the data line DL, the second reference voltage line VRL2, a first connection pattern 1310, a second connection pattern 1320, a third connection pattern 1330, the fourth connection pattern 1340, a fifth connection pattern 1350, a sixth connection pattern 1360, and a seventh connection pattern 1370.

The fourth insulating layer 114 may include an inorganic insulating material. The fourth insulating layer 114 may include silicon oxide, silicon nitride, silicon oxynitride, or aluminum oxide, for example.

The first source-drain layer SDL1 may include a metal, an alloy, a conductive metal oxide, or a transparent conductive material. In an embodiment, the first source-drain layer SDL1 may include silver (Ag), an alloy including or consisting of silver, molybdenum (Mo), an alloy including or consisting of molybdenum, aluminum (Al), an alloy including or consisting of aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), or indium zinc oxide (“IZO”), for example. A source-drain layer SD may have a multi-layer structure, and for example, the source-drain layer SD may have a two-layer structure including Ti/Al or a three-layer structure including Ti/Al/Ti.

Each of the data line DL, the first connection pattern 1310, the second connection pattern 1320, the third connection pattern 1330, the fourth connection pattern 1340, the fifth connection pattern 1350, the sixth connection pattern 1360, and the seventh connection pattern 1370 may be disposed to correspond to each of the first pixel circuit PC1, the second pixel circuit PC2, and the third pixel circuit PC3.

The data line DL may extend in the second direction (e.g., the y-axis direction) intersecting the first direction (e.g., the x-axis direction). The data line DL may be electrically connected to the second drain region D2 (refer to FIG. 12) of the second semiconductor layer A2 of the second transistor T2 through a first contact hole CNT1 passing through at least one insulating layer disposed between the second semiconductor layer A2 and the data line DL. The data line DL may be disposed to correspond to each of the first pixel circuit PC1, the second pixel circuit PC2, and the third pixel circuit PC3, and for example, the data line DL disposed in the first pixel circuit PC1 may transmit a data signal to a red pixel, the data line DL disposed in the second pixel circuit PC2 may transmit a data signal to a green pixel, and the data line DL disposed in the third pixel circuit PC3 may transmit a data signal to a blue pixel. In an embodiment, the data lines DL respectively disposed in the first pixel circuit PC1, the second pixel circuit PC2, and the third pixel circuit PC3 may be electrically connected to the second transistor T2 of the first pixel PX1, the second transistor T2 of the second pixel PX2, and the second transistor T2 of the third pixel PX3, respectively, for example.

The first connection pattern 1310 may be electrically connected to the first semiconductor pattern 1110 (refer to FIG. 12) through a second contact hole CNT2 passing through at least one insulating layer disposed between the first connection pattern 1310 and the first semiconductor pattern 1110 (refer to FIG. 12). In an embodiment, the first connection pattern 1310 may be connected to the first source region S1 (refer to FIG. 12) of the first semiconductor layer A1 of the first transistor T1 through the second contact hole CNT2, for example.

The first connection pattern 1310 may be electrically connected to the third semiconductor pattern 1130 (refer to FIG. 12) through a third contact hole CNT3 passing through at least one insulating layer disposed between the first connection pattern 1310 and the third semiconductor pattern 1130 (refer to FIG. 12). In an embodiment, the first connection pattern 1310 may be connected to the sixth drain region D6 (refer to FIG. 12) of the sixth semiconductor layer A6 of the sixth transistor T6 through the third contact hole CNT3, for example.

The first connection pattern 1310 may include the upper electrode CE3 of the storage capacitor Cst. The first connection pattern 1310 may partially overlap the third conductive pattern 1210 (refer to FIG. 13) and the first conductive pattern 1020 (refer to FIG. 11). A portion of the first connection pattern 1310 overlapping the third conductive pattern 1210 (refer to FIG. 13) and the first conductive pattern 1020 (refer to FIG. 11) in a plan view may be the upper electrode CE3 of the storage capacitor Cst. The upper electrode CE3 of the storage capacitor Cst may be electrically connected to the lower electrode CE1 (refer to FIG. 12) of the storage capacitor Cst by a fourth contact hole CNT4 passing through at least one insulating layer disposed between the upper electrode CE3 of the storage capacitor Cst and the lower electrode CE1 of the storage capacitor Cst. The upper electrode CE3 of the storage capacitor Cst may overlap the lower electrode CE1 (refer to FIG. 12) and the intermediate electrode CE2 (refer to FIG. 13) of the storage capacitor Cst to constitute the storage capacitor Cst.

The second connection pattern 1320 may connect the second gate electrode G2 of the second transistor T2 to the second write gate line GWLb. The second connection pattern 1320 may be electrically connected to the second write gate line GWLb through a fifth contact hole CNT5 passing through at least one insulating layer disposed between the second connection pattern 1320 and the second write gate line GWLb. In an embodiment, the second connection pattern 1320 may be directly connected to the second write gate line GWLb through the fifth contact hole CNT5 without a separate contact metal, for example.

The third connection pattern 1330 may connect the second semiconductor pattern 1120 to the third conductive pattern 1210. The third connection pattern 1330 may be electrically connected to the second semiconductor pattern 1120 and the third conductive pattern 1210 through a sixth contact hole CNT6 and a seventh contact hole CNT7 passing through at least one insulating layer disposed between the third connection pattern 1330 and the second semiconductor pattern 1120 and between the third connection pattern 1330 and the third conductive pattern 1210. In an embodiment, one side of the third connection pattern 1330 may be connected to the second semiconductor pattern 1120 through the sixth contact hole CNT6, and an opposite side of the third connection pattern 1330 may be connected to the third conductive pattern 1210 through the seventh contact hole CNT7, for example. The third connection pattern 1330 may connect the second drain region D2 (refer to FIG. 11) of the second semiconductor layer A2 of the second transistor T2, the third drain region D3 (refer to FIG. 12) of the third semiconductor layer A3 of the third transistor T3, and the first gate electrode G1 of the first transistor T1 to each other. The third connection pattern 1330 may connect the second drain region D2 (refer to FIG. 12) of the second semiconductor layer A2 of the second transistor T2, the third drain region D3 (refer to FIG. 12) of the third semiconductor layer A3 of the third transistor T3, and the lower electrode CE1 of the storage capacitor Cst to each other.

The second reference voltage line VRL2 may extend in the second direction (e.g., the y-axis direction). The second reference voltage line VRL2 may be disposed in a symmetrical shape between the first pixel circuit PC1 and the second pixel circuit PC2 and may be shared by the first pixel PX1 and the second pixel PX2. The second reference voltage line VRL2 may be electrically connected to the second semiconductor pattern 1120 (refer to FIG. 12) through an eighth contact hole CNT8. Also, the second reference voltage line VRL2 may be electrically connected to the first reference voltage line VRL1 (refer to FIG. 10) through the eighth contact hole CNT8. Accordingly, the reference voltage Vref may be applied to the third source region S3 of the third semiconductor layer A3 of the third transistor T3 through the second reference voltage line VRL2.

The fourth connection pattern 1340 may be disposed in the third pixel circuit PC3 and may perform the same function as the second reference voltage line VRL2. In other words, the fourth connection pattern 1340 may electrically connect the first reference voltage line VRL1 to the second semiconductor pattern 1120 through a contact hole passing through at least one insulating layer. Accordingly, the reference voltage Vref may be applied to the third source region S3 (refer to FIG. 12) of the third semiconductor layer A3 of the third transistor T3 of the third pixel circuit PC3 through the fourth connection pattern 1340.

The fifth connection pattern 1350 may be a pattern disposed to enable connection between the repair line RL (refer to FIG. 10) and a pixel circuit when a defect occurs in a signal line or a voltage line included in the pixel circuit. The second conductive pattern 1030 may be connected to the repair line RL (refer to FIG. 10) through the fifth connection pattern 1350 when a defect occurs in a signal line or a voltage layer. In an embodiment, the fifth connection pattern 1350 may be electrically connected to the second conductive pattern 1030 (refer to FIG. 11), which is a repair pattern, and the third semiconductor pattern 1130 (refer to FIG. 12) through a ninth contact hole CNT9 and a tenth contact hole CNT10, for example.

The sixth connection pattern 1360 may be electrically connected to the third semiconductor pattern 1130 and the first initialization voltage line VAL1 through an 11^{th} contact hole CNT11 and a 12^{th} contact hole CNT12 passing through at least one insulating layer. In an embodiment, one side of the sixth connection pattern 1360 may be connected to the third semiconductor pattern 1130 through the 11th contact hole CNT11, and an opposite side of the sixth connection pattern 1360 may be connected to the first initialization voltage line VAL1 through the 12th contact hole CNT12, for example. In detail, the sixth connection pattern 1360 disposed in the first pixel circuit PC1 may connect the first initialization voltage line VAL1 to the fourth source region S4 of the fourth semiconductor layer A4 of the fourth transistor T4 of the first pixel circuit PC1. The sixth connection pattern 1360 disposed in the second pixel circuit PC2 may connect the second initialization voltage line VAL2 to the fourth source region S4 of the fourth semiconductor layer A4 of the fourth transistor T4 of the second pixel circuit PC2, and the sixth connection pattern 1360 disposed in the third pixel circuit PC3 may connect the third initialization voltage line VAL3 to the fourth source region S4 of the fourth semiconductor layer A4 of the fourth transistor T4 of the third pixel circuit PC3.

The seventh connection pattern 1370 may be electrically connected to the first semiconductor pattern 1110 and the lower driving voltage line PL0 through a 13^{th} contact hole CNT13 and a 14^{th} contact hole CNT14 passing through at least one insulating layer. In an embodiment, one side of the seventh connection pattern 1370 may be connected to the first semiconductor pattern 1110 through the 13th contact hole CNT13, and an opposite side of the seventh connection pattern 1370 may be connected to the lower conductive pattern 1010 through the 14th contact hole CNT14, for example. In detail, the seventh connection pattern 1370 may electrically connect the lower conductive pattern 1010 to the fifth drain region D5 of the fifth semiconductor layer A5 of the fifth transistor T5 to apply the driving voltage ELVDD to the fifth transistor T5.

Referring to FIGS. 15 and 18 together, a fifth insulating layer 115 may be disposed on the first source-drain layer SDL1, and a second source-drain layer (also referred to as a second conductive layer) SDL2 may be disposed on the fifth insulating layer 115. The second source-drain layer SDL2 may include the second common voltage line SS2, the third common voltage line SS3, the first upper driving voltage line PL11, the second upper driving voltage line PL12, a fourth initialization voltage line VAL4, a fifth conductive pattern 1410, a sixth conductive pattern 1420, a seventh conductive pattern 1430, an eighth conductive pattern 1440, a ninth conductive pattern 1450, and a tenth conductive pattern 1460.

The fifth insulating layer 115 is a planarization layer and may include an organic insulating material. The fifth insulating layer 115 may be an organic insulating layer including an organic insulating material such as acryl, benzocyclobutene (“BCB”), polyimide, or hexamethyldisiloxane (“HMDSO”).

The second source-drain layer SDL2 may include a metal, an alloy, a conductive metal oxide, or a transparent conductive material. In an embodiment, the second source-drain layer SDL2 may include silver (Ag), an alloy including or consisting of silver, molybdenum (Mo), an alloy including or consisting of molybdenum, aluminum (Al), an alloy including or consisting of aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), or indium zinc oxide (“IZO”), for example. The source-drain layer SD may have a multi-layer structure, and for example, the second source-drain layer SDL2 may have a two-layer structure including Ti/Al or a three-layer structure including Ti/Al/Ti.

The third common voltage line SS3, the first upper driving voltage line PL11, the fifth conductive pattern 1410, and the sixth conductive pattern 1420 may be disposed to correspond to the first pixel circuit PC1. The second upper driving voltage line PL12, the seventh conductive pattern 1430, and the eighth conductive pattern 1440 may be disposed to correspond to the second pixel circuit PC2. The third common voltage line SS3 may be disposed across the second pixel circuit PC2 and the third pixel circuit PC3, and may be disposed in a symmetrical shape with respect to a virtual line along the second direction (e.g., the y-axis direction). The fourth initialization voltage line VAL4, the ninth conductive pattern 1450, and the tenth conductive pattern 1460 may be disposed to correspond to the third pixel circuit PC3.

The second common voltage line SS2 may extend in the second direction (e.g., the y-axis direction). The third common voltage line SS3 may have a symmetrical shape with respect to a virtual line along the second direction (e.g., the y-axis direction). The virtual line may be a virtual line disposed between the second pixel circuit PC2 and the third pixel circuit PC3 to define a boundary between the second pixel circuit PC2 and the third pixel circuit PC3, and the second common voltage line SS2 may be disposed on the virtual line. The second common voltage line SS2 may be electrically connected to the first common voltage line SS1 described below with reference to FIG. 16 to form a horizontal-vertical mesh structure in the display area DA (refer to FIG. 8). In an embodiment, a first width W1 of the second common voltage line SS2 may be greater than a second width W2 of the third common voltage line SS3.

The third common voltage line SS3 may extend in the second direction (e.g., the y-axis direction). The third common voltage line SS3 may be a vertical common voltage line that is vertically disposed in a plan view of FIG. 14. The third common voltage line SS3 may be disposed along the second direction (e.g., the y-axis direction) and may extend to the peripheral area PA (refer to FIG. 6). The third common voltage line SS3 may be electrically connected to the common voltage supply line 30 in the peripheral area PA (refer to FIG. 6) to apply the common voltage ELVSS to the third common voltage line SS3.

The fourth initialization voltage line VAL4 may extend substantially in the second direction (e.g., the y-axis direction). The fourth initialization voltage line VAL4 may be a vertical initialization voltage line that is vertically disposed in a plan view of FIG. 14. The fourth initialization voltage line VAL4 may be disposed to correspond to the third pixel circuit PC3, and may be electrically connected to the sixth connection pattern 1360 (refer to FIG. 13). The fourth initialization voltage line VAL4 may be electrically connected to the sixth connection pattern 1360 (refer to FIG. 13) to transmit an initialization voltage to the fourth transistor T4 (refer to FIG. 7) of the third pixel circuit PC3. The fourth initialization voltage line VAL4 and the sixth connection pattern 1360 may be electrically connected through a first via contact hole VCNT1 passing through at least one insulating layer disposed to correspond to the third pixel circuit PC3.

The upper driving voltage line PL1 may extend substantially in the second direction (e.g., the y-axis direction). The upper driving voltage line PL1 may include the first upper driving voltage line PL11 disposed to correspond to the first pixel circuit PC1 and the second upper driving voltage line PL12 disposed to correspond to the second pixel circuit PC2. The upper driving voltage line PL1 may be electrically connected to the lower driving voltage line PL0 (refer to FIG. 10). As such, as the lower driving voltage line PL0 and the upper driving voltage line PL1 are electrically connected to each other, the driving voltage line PL (refer to FIG. 7) may be provided in a mesh shape in the display area DA.

The first upper driving voltage line PL11 may be electrically connected to the seventh connection pattern 1370 (refer to FIG. 14) disposed to correspond to the first pixel circuit PC1 through a second via contact hole VCNT2. The first upper driving voltage line PL11 may be electrically connected to the first hold electrode CEh1 (refer to FIG. 7) of the first pixel circuit PC1 and the fifth semiconductor layer A5 (refer to FIG. 13) of the fifth transistor T5 (refer to FIG. 13). In detail, the seventh connection pattern 1370 may be electrically connected to the lower driving voltage line PL0 (refer to FIG. 10), which is a horizontal driving voltage line, through the 14^{th} contact hole CNT14 described with reference to FIG. 14 and electrically connected to the first upper driving voltage line PL11, which is a vertical driving voltage line, through the second via contact hole VCNT2, to form a mesh structure in the display area DA. Also, the seventh connection pattern 1370 may be electrically connected to the first semiconductor pattern 1110 through the 13^{th} contact hole CNT13 and electrically connected to the first upper driving voltage line PL11, which is a vertical driving voltage line, through the second via contact hole VCNT2, to transmit the driving voltage ELVDD to the fifth semiconductor layer A5 (refer to FIG. 13) of the fifth transistor T5 (refer to FIG. 13) of the first pixel circuit PC1.

The second upper driving voltage line PL12 may be electrically connected to the seventh connection pattern 1370 (refer to FIG. 14) disposed to correspond to the second pixel circuit PC2 through a third via contact hole VCNT3. The second upper driving voltage line PL12 may be electrically connected to the first hold electrode CEh1 (refer to FIG. 7) of the second pixel circuit PC2 and the fifth semiconductor layer A5 (refer to FIG. 13) of the fifth transistor T5 (refer to FIG. 13). In detail, the seventh connection pattern 1370 may be electrically connected to the lower driving voltage line PL0, which is a horizontal driving voltage line, through the 14^{th} contact hole CNT14 described with reference to FIG. 14 and electrically connected to the second upper driving voltage line PL12, which is a vertical driving voltage line, through the third via contact hole VCNT3, to form a mesh structure in the display area DA. Also, the seventh connection pattern 1370 may be electrically connected to the first semiconductor pattern 1110 through the 13^{th} contact hole CNT13 and electrically connected to the second upper driving voltage line PL12, which is a vertical driving voltage line, through the third via contact hole VCNT3, to transmit the driving voltage ELVDD to the fifth semiconductor layer A5 (refer to FIG. 13) of the fifth transistor T5 (refer to FIG. 13) of the second pixel circuit PC2.

In a plan view of FIG. 15, the second upper driving voltage line PL12 may have a substantially ladder shape. In detail, the second upper driving voltage line PL12 may extend substantially in the second direction (e.g., the y-axis direction), and a plurality of openings PL1-OP may be defined in the second upper driving voltage line PL12. The plurality of openings PL1-OP provided in the second upper driving voltage line PL12 may be repeatedly provided with the seventh connection pattern 1370 and an eighth connection pattern 1380 therebetween. Out-gassing generated from an insulating layer (e.g., the fifth insulating layer 115) including an organic material and disposed under the second upper driving voltage line PL12 may be effectively output to the outside through the plurality of openings PL1-OP provided in the second upper driving voltage line PL12.

The plurality of openings PL1-OP provided in the second upper driving voltage line PL12 may be disposed not to overlap openings 117OP of a pixel-defining film 117 through which central portions of the first to third pixel electrodes PE1, PE2, and PE3 described below with reference to FIG. 18 are exposed. This may be to prevent a decrease in light emission efficiency when a profile of top surfaces of the pixel electrodes PE becomes uneven due to the plurality of openings PL1-OP provided in the second upper driving voltage line PL12. Also, a second width W12 of the second upper driving voltage line PL12 along the first direction (e.g., the x-axis direction) may be greater than a first width W11 of the first upper driving voltage line PL11 along the first direction (e.g., the x-axis direction).

The fifth conductive pattern 1410 and the sixth conductive pattern 1420 may be disposed to correspond to the first pixel circuit PC1, the seventh conductive pattern 1430 and the eighth conductive pattern 1440 may be disposed to correspond to the second pixel circuit PC2, and the ninth conductive pattern 1450 and the tenth conductive pattern 1460 may be disposed to correspond to the third pixel circuit PC3. Each of the fifth conductive pattern 1410 to the tenth conductive pattern 1460 may have an isolated shape in a plan view.

In the first pixel circuit PC1, the second pixel circuit PC2, and the third pixel circuit PC3, the fifth conductive pattern 1410, the seventh conductive pattern 1430, and the ninth conductive pattern 1450 may perform the same function. Each of the fifth conductive pattern 1410, the seventh conductive pattern 1430, and the ninth conductive pattern 1450 may have a substantially quadrangular shape in a plan view. Each of the fifth conductive pattern 1410, the seventh conductive pattern 1430, and the ninth conductive pattern 1450 may be electrically connected to the first connection pattern 1310 (refer to FIG. 14) through a fourth via contact hole VCNT4, and may have a shape covering the third connection pattern 1330 (refer to FIG. 14). As each of the fifth conductive pattern 1410, the seventh conductive pattern 1430, and the ninth conductive pattern 1450 shields the third connection pattern 1330 (refer to FIG. 14) (or a first node electrode) connected to the storage capacitor Cst (refer to FIG. 13), image quality may be improved.

In the first pixel circuit PC1, the second pixel circuit PC2, and the third pixel circuit PC3, the sixth conductive pattern 1420, the eighth conductive pattern 1440, and the tenth conductive pattern 1460 may perform the same function. The sixth conductive pattern 1420, the eighth conductive pattern 1440, and the tenth conductive pattern 1460 may electrically connect the light-emitting diodes LED described below with reference to FIG. 18 to the pixel circuits PC through a fifth via contact hole VCNT5 passing through at least one insulating layer disposed on the second source-drain layer SDL2. In detail, the first pixel electrode PE1 may be connected to the fourth transistor T4 (refer to FIG. 13) and the sixth transistor T6 (refer to FIG. 13) of the first pixel circuit PC1 through the sixth conductive pattern 1420 disposed in the first pixel circuit PC1. Also, the second pixel electrode PE2 may be connected to the fourth transistor T4 (refer to FIG. 13) and the sixth transistor T6 (refer to FIG. 13) of the second pixel circuit PC2 through the eighth conductive pattern 1440 disposed to correspond to the second pixel circuit PC2. Also, the third pixel electrode PE3 may be connected to the fourth transistor T4 (refer to FIG. 13) and the sixth transistor T6 (refer to FIG. 13) of the third pixel circuit PC3 through the tenth conductive pattern 1460 disposed to correspond to the third pixel circuit PC3.

Referring to FIGS. 16 and 18, a sixth insulating layer 116 may be disposed on the second source-drain layer SDL2, and a pixel electrode layer PXL may be disposed on the sixth insulating layer 116. The pixel electrode layer PXL may include a pixel electrode PE and an auxiliary electrode AE.

The sixth insulating layer 116 is a planarization layer and may include an organic insulating material. The sixth insulating layer 116 may be an organic insulating layer including an organic insulating material such as acryl, benzocyclobutene (“BCB”), polyimide, or hexamethyldisiloxane (“HMDSO”).

The pixel electrode PE may include the first pixel electrode PE1 emitting light having a first wavelength, the second pixel electrode PE2 emitting light having a second wavelength, and the third pixel electrode PE3 emitting light having a third wavelength. In an embodiment, the first pixel electrode PE1 may emit first color light corresponding to red, the second pixel electrode PE2 may emit second color light corresponding to green, and the third pixel electrode PE3 may emit third color light corresponding to blue.

The pixel electrode PE may include the first pixel electrode PE1 electrically connected to the first pixel circuit PC1, the second pixel electrode PE2 electrically connected to the second pixel circuit PC2, and the third pixel electrode PE3 electrically connected to the third pixel circuit PC3. As such, although the first to third pixel electrodes PE1, PE2, and PE3 are respectively electrically connected to the first to third pixel circuits PC1, PC2, and PC3, positions of the first to third pixel electrodes PE1, PE2, and PE3 do not have to correspond to areas where the first to pixel circuits PC1, PC2, and PC3 are disposed. In an embodiment, the first pixel electrode PE1 and the second pixel electrode PE2 may be disposed to partially or entirely correspond to an area where the first pixel circuit PC1 is disposed. The third pixel electrode PE3 may be disposed across an area where the second pixel circuit PC2 is disposed and an area where the third pixel circuit PC3 is disposed. The first pixel electrode PE1 and the second pixel electrode PE2 may be disposed in the same column (e.g., a first column) along the second direction (e.g., the y-axis direction) and may be alternately disposed. The third pixel electrodes PE3 may be disposed in the same column (e.g., a second column) next (adjacent) to the first column.

The pixel electrode PE may be a (semi)transmissive electrode or a reflective electrode. In an embodiment, the pixel electrode PE may include a reflective layer including Ag, Mg, Al, Pt, Pd, Au, Ni, Nd, Ir, Cr, or any combinations thereof, and a transparent or semitransparent electrode layer disposed on the reflective layer, for example. The transparent or semitransparent electrode layer may include at least one selected from the group consisting of indium tin oxide (“ITO”), indium zinc oxide (“IZO”), zinc oxide (ZnOx: ZnO or ZnO₂), indium oxide (In₂O₃), indium gallium oxide (“IGO”), and aluminum zinc oxide (“AZO”). In an embodiment, the pixel electrode PE may have a three-layer structure including ITO/Ag/ITO, for example.

The auxiliary electrode AE may extend substantially in the first direction (e.g., the x-axis direction). The auxiliary electrode AE may be disposed in the same layer as the pixel electrode PE and may include the same material as each other. The auxiliary electrode AE may be spaced apart from the pixel electrode PE.

The auxiliary electrode AE may include the plurality of pad units AEP and a connection portion AEC connecting the plurality of pad units AEP. The plurality of pad units AEP may be disposed in the same column (e.g., the second column) as the column in which the third pixel electrodes PE3 are disposed, and the third pixel electrode PE3 and the pad unit AEP may be alternately disposed. The plurality of pad units AEP may be connected to each other through the connection portion AEC extending in the first direction (e.g., the x-axis direction). The plurality of pad units AEP disposed next (adjacent) to each other may be integrally connected through the connection portion AEC.

The auxiliary electrode AE may be also referred to as the first common voltage line SS1. That is, the auxiliary electrode AE may function as the first common voltage line SS1, and thus, the common voltage ELVSS may be applied to the auxiliary electrode AE. In a plan view of FIG. 16, the first common voltage line SS1 may be a horizontal common voltage line. The first common voltage line SS1, which is a horizontal common voltage line, may be electrically connected to the second common voltage line SS2, which is a vertical common voltage line, to form a mesh structure in the display area DA (refer to FIG. 6).

As the auxiliary electrode AE functions as the first common voltage line SS1, the first common voltage line SS1 may include the plurality of pad units AEP and the connection portion AEC. Accordingly, the first common voltage line SS1 may extend in the first direction (e.g., the x-axis direction).

Referring to FIGS. 16 and 17 together, FIG. 17 is a cross-sectional view mainly illustrating the second common voltage line SS2 included in the second source-drain layer SDL2 and the first pad unit AEP1 included in the pixel electrode layer PXL, and other layers constituting a pixel circuit are not shown. It is to be understood that layers constituting the pixel circuit described with reference to FIGS. 10 to 14 may be provided under the second source-drain layer SDL2.

FIGS. 16 and 17 illustrate the first pad unit AEP1 described with reference to FIGS. 8 and 9 among the plurality of pad units AEP. As shown in FIG. 17, the plurality of pad units AEP (i.e., the first pad unit AEP1) may be electrically connected to the second common voltage line SS2 through the first contact portion PCNT1 passing through at least one insulating layer. The first contact portion PCNT1 may be disposed at a central portion of the first pad unit AEP1, and may also be disposed substantially at a central portion of the second common voltage line SS2 in a width direction along the first direction (e.g., the x-axis direction).

Referring to FIGS. 9, 16, and 18, together, the light-emitting diode LED may include a pixel electrode 210, an intermediate layer 220 including an emission layer 222, and a counter electrode 230. The pixel electrode 210 of FIG. 18 may be one of the first pixel electrode PE1, the second pixel electrode PE2, and the third pixel electrode PE3 described with reference to FIG. 16.

The pixel-defining film 117 may be disposed on the pixel electrode 210. That is, the patterned pixel electrode 210 may be disposed on the sixth insulating layer 116, and the pixel-defining film 117 may be disposed on the sixth insulating layer 116 while covering at least a part of the pixel electrode 210. The pixel-defining film 117 may cover an edge of the pixel electrode 210 and increase a distance between the pixel electrode 210 and the counter electrode 230 over the pixel electrode 210, thereby preventing an arc or the like from occurring at the edge of the pixel electrode 210. The pixel-defining film 117 may have the opening 117OP through which a central portion of the pixel electrode 210 is exposed. The central portion of the pixel electrode PE exposed through the opening 117OP of the pixel-defining film 117 may be defined as an emission area EA.

The pixel-defining film 117 may include or consist of at least one organic insulating material selected from the group consisting of polyimide, polyamide, an acrylic resin, benzocyclobutene, and a phenolic resin by spin coating or the like. In another embodiment, the pixel-defining film 117 may include an organic insulating material including a light-blocking material. In an alternative embodiment, the pixel-defining film 117 may include a polyimide (“PI”)-based binder, and a pigment in which red, green, and blue colors are mixed. In an alternative embodiment, the pixel-defining film 117 may include a cardo-based binder resin, and a combination of a lactam black pigment and a blue pigment. In an alternative embodiment, the pixel-defining film 117 may include carbon black. Because the pixel-defining film 117 includes a colored material, contrast of the display apparatus 10 may be improved.

A spacer layer 119 may be disposed on the pixel-defining film 117. The spacer layer 119 may include a material different from that of the pixel-defining film 117. In an embodiment, the pixel-defining film 117 and the spacer layer 119 may include different materials; for example, the pixel-defining film 117 may include a negative photosensitive material and the spacer layer 119 may include a positive photosensitive material, and the pixel-defining film 117 and the spacer layer 119 may be formed by separate mask processes, for example. In another embodiment, the spacer layer 119 may include the same material as that of the pixel-defining film 117 and may be formed together in the same mask process (e.g., a halftone mask process).

At least a part of the intermediate layer 220 including the emission layer of the light-emitting diode LED may be disposed in the opening 117OP defined in the pixel-defining film 117. The intermediate layer 220 may include the emission layer. The emission layer 222 may include a relatively high molecular weight organic material or a relatively low molecular weight organic material that emits light of a predetermined color. The emission layer 222 may include a material emitting red light, green light, or blue light according to the light-emitting diode LED.

A functional layer may be further included under and/or over the emission layer 222. In an embodiment, a first functional layer 221 may be further included between the pixel electrode 210 and the emission layer 222, and a second functional layer 223 may be further included between the emission layer 222 and the counter electrode 230 described below, for example. The first functional layer 221 may include a hole transport layer (“HTL”) and/or a hole injection layer (“HIL”). The second functional layer 223 may include an electron transport layer (“ETL”) and/or an electron injection layer (“EIL”).

The emission layer 222 may have a shape that is patterned to correspond to the pixel electrode 210. However, various modifications may be made; for example, layers other than the emission layer 222 included in the intermediate layer 220 may be integrally formed (or unitary) over the plurality of pixel electrodes 210.

The counter electrode 230 may be a transmissive electrode or a reflective electrode. In an embodiment, the counter electrode 230 may be a transparent or semitransparent electrode, and may include a metal thin film having a relatively low work function including Li, Ca, Al, Ag, Mg, or any combinations thereof (e.g., LiF). Also, the counter electrode 230 may further include a transparent conductive oxide (“TCO”) film such as ITO, IZO, ZnO, ZnO2, or In2O3 disposed on the metal thin film, for example.

The counter electrode 230 may be integrally formed (or unitary) over an entirety of the surface of the display area DA to cover the display area DA, and may be disposed on the intermediate layer 220 and the pixel-defining film 117. That is, each of the pixel electrodes 210 may be disposed to correspond to the light-emitting diode LED, and the counter electrode 230 may be integrally formed (or unitary) to correspond to the plurality of light-emitting diodes LED. The plurality of light-emitting diodes LED may share the counter electrode 230, and a stacked structure of the pixel electrode 210, the intermediate layer 220, and the counter electrode 230 may correspond to the light-emitting diode LED.

When desired, an encapsulation layer may be disposed on the light-emitting diode LED. The encapsulation layer may include a first inorganic encapsulation layer and a second inorganic encapsulation layer, and an organic encapsulation layer disposed between the first and second inorganic encapsulation layers.

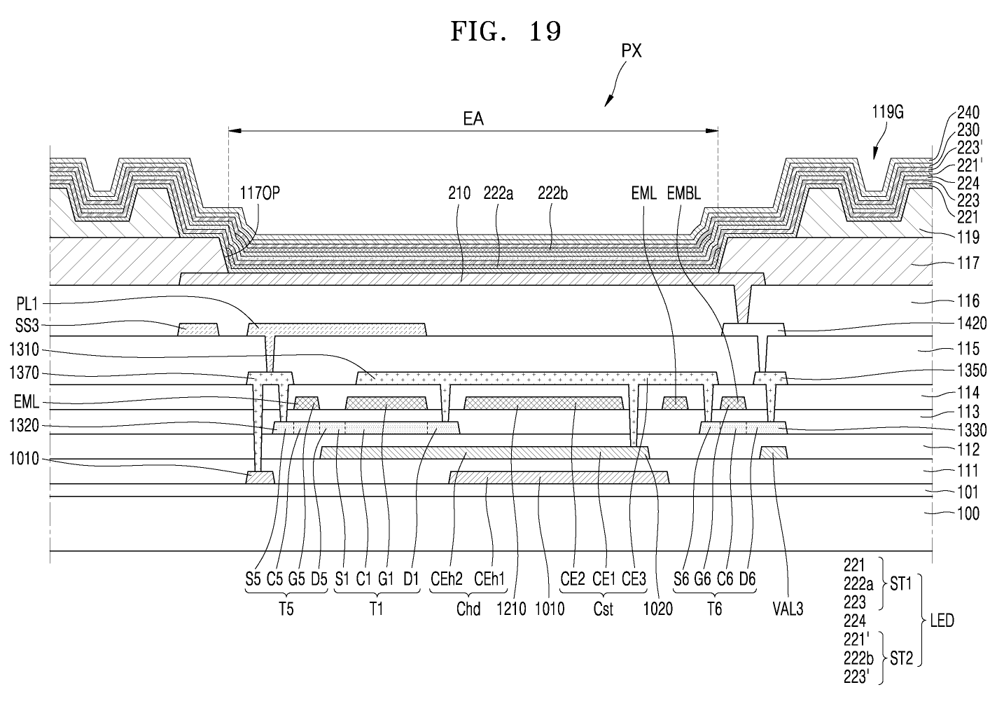

FIG. 19 is a cross-sectional view schematically illustrating an embodiment of a part of a display apparatus. FIG. 19 may correspond to a modified example of FIG. 18.

Referring to FIG. 19, a structure of the pixel circuit PC described with reference to FIG. 18 is the same, but there is a difference in structures of the light-emitting diode LED and the spacer layer 119 disposed on the light-emitting diode LED. Hereinafter, the difference related to the light-emitting diode LED and the spacer layer 119 disposed on the light-emitting diode LED will be mainly described.

In an embodiment, the light-emitting diode LED may be a tandem-type light-emitting diode LED including a plurality of emission layers (e.g., 222a and 222b) that are vertically stacked.

The intermediate layer 220 may include a first stack ST1 including a first emission layer 222a and the first and second functional layers 221 and 223 disposed with the first emission layer 222a therebetween, a second stack ST2 including a second emission layer 222b and first and second functional layers 221’ and 223’ disposed with the second emission layer 222b therebetween, and a charge generation layer 224 between the first stack ST1 and the second stack ST2. In the first stack ST1 and the second stack ST2, the first and second functional layers 221 and 223 and the first and second functional layers 221’ and 223’ may all be provided or some may be omitted.

The charge generation layer 224 may include a negative charge generation layer and a positive charge generation layer. In the case of a tandem-type light-emitting diode LED including a plurality of emission layers by the negative charge generation layer and the positive charge generation layer, light emission efficiency may be further increased.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer include a host and a dopant. The host may include an organic material. The dopant may include a metal material.

A groove 119G may be disposed in the spacer layer 119. The groove 119G may surround at least a part of the emission area EA of the pixel PX in a plan view. When the tandem-type light-emitting diode LED is provided as described above, the groove 119G may cause at least a part of the charge generation layer 224 to be disconnected due to a stepped portion of the groove 119G. In other words, the charge generation layer 224 may be discontinuously provided in at least a portion due to the stepped portion of the groove 119G disposed in the spacer layer 119. As the groove 119G surrounds at least a part of the emission area EA of the pixel PX, the charge generation layer 224 may be discontinuously provided to surround at least a part of the emission area EA of the pixel PX. Accordingly, leakage of current occurring between the pixels PX may be prevented, thereby minimizing color mixing of light between the pixels PX. In an embodiment, the pixels PX may further include a protective layer (or encapsulation layer) 240 disposed on the counter electrode 230.

FIG. 20 is a cross-sectional view schematically illustrating an embodiment of a part of a display apparatus of the disclosure, and FIG. 20 may correspond to an enlarged structure illustrating a portion B of FIG. 8. FIG. 21 is a cross-sectional view schematically taken along line C-C’ of FIG. 20.

Referring to FIGS. 20 and 21, the display apparatus 10 may have a structure in which the first pixel PX1, the second pixel PX2, and the third pixel PX3 sequentially disposed in the first direction (e.g., the x-axis direction) are repeatedly disposed in the first direction (e.g., the x-axis direction) and the second direction (e.g., the y-axis direction). In an embodiment, the first pixel circuit PC1 of the first pixel PX1 may be a first color (e.g., red) pixel circuit, the second pixel circuit PC2 of the second pixel PX2 may be also referred to as a second color (e.g., green) pixel circuit, and the third pixel circuit PC3 of the third pixel PX3 may be also referred to as a third color (e.g., blue) pixel circuit, for example.

Areas where the first pixel PX1, the second pixel PX2, and the third pixel PX3 are disposed may be areas where the first pixel circuit PC1 included in the first pixel PX1, the second pixel circuit PC2 included in the second pixel PX2, and the third pixel circuit PC3 included in the third pixel PX3 are disposed. However, light-emitting diodes included in the first to third pixels PX1, PX2, and PX3 do not have to be disposed in areas corresponding to the first to third pixel circuits PC1, PC2, and PC3. In an embodiment, as shown in FIG. 20, the first pixel electrode PE1 included in the first pixel PX1 may be disposed across an area corresponding to the first pixel circuit PC1 and may extend in the -y direction, the second pixel electrode PE2 included in the second pixel PX2 may be disposed in the +y direction from the first pixel electrode PE1 and disposed in the area corresponding to the first pixel circuit PC1, and the third pixel electrode PE3 included in the third pixel PX3 may be disposed across an area corresponding to the second pixel circuit PC2 and an area corresponding to the third pixel circuit PC3 and extend in the -y direction, for example. In other words, the first pixel electrode PE1 and the second pixel electrode PE2 may be disposed in the same column (e.g., a first column) along the second direction (e.g., the y-axis direction), and may be alternately disposed. The third pixel electrodes PE3 may be disposed in a column (e.g., a second column) next (adjacent) to the column in which the first pixel electrode PE1 and the second pixel electrode PE2 are arranged.

The plurality of pad units AEP (refer to FIG. 8) may be disposed between the third pixel electrodes PE3 arranged in the second direction (e.g., the y-axis direction). In an embodiment, the pad unit AEP may be disposed in the same column (e.g., the second column) as the third pixel electrodes PE3, and may be alternately disposed with the third pixel electrodes PE3, for example. As described with reference to FIG. 8, the plurality of pad units AEP may include the second pad unit AEP2, and the second pad unit AEP2 is illustrated in FIGS. 20 and 21.

In an embodiment, an upper insulating layer UIL may be disposed on the second pad unit AEP2. The upper insulating layer UIL may include the pixel-defining film 117 and the spacer layer 119 described with reference to FIG. 18 or the like. The upper insulating layer UIL may include both the pixel-defining film 117 and the spacer layer 119 or may include only one of the pixel-defining film 117 and the spacer layer 119.

The second pad unit AEP2 may include a main portion AEP2m having a substantially circular shape and a protruding portion AEP2p protruding in at least one direction. Although the second pad unit AEP2 is described with reference to FIG. 20, a structure of the first pad unit AEP1 may be the same.

The upper insulating layer UIL may define an opening LDH through which a central portion of the second pad unit AEP2 is exposed. The opening LDH may be defined in the main portion AEP2m of the second pad unit AEP2. As shown in FIG. 21, the counter electrode 230 and the second pad unit AEP2 disposed on the upper insulating layer UIL may directly contact each other through the opening LDH. In an embodiment, the opening LDH defined in the upper insulating layer UIL may be formed through a laser drilling process, for example. That is, the opening LDH defined in the upper insulating layer UIL may be a laser drilling hole. The laser drilling process involves emitting a laser to a cathode (e.g., the counter electrode 230) in a state where the cathode has been formed to melt and remove an insulating layer (e.g., the upper insulating layer UIL) between the cathode and a laser drilling pad (e.g., the second pad unit AEP2), thereby electrically connecting the cathode to the laser drilling pad. The opening LDH may be defined in a portion where the upper insulating layer UIL is removed through the laser drilling process. In an embodiment, the opening LDH may be provided so that an end 117e of the pixel-defining film 117 is covered by an end 119e of the spacer layer 119, for example.

The second pad unit AEP2 may include the protruding portion AEP2p protruding in at least one direction on one side. In an embodiment, in a plan view of FIG. 20, the protruding portion AEP2p may extend substantially in a -x direction, for example. The second contact portion PCNT2 may be disposed in the protruding portion AEP2p. The second contact portion PCNT2 may be connected to a fourth common voltage line SS4 disposed under the second pad unit AEP2. As the second pad unit AEP2 is electrically connected to the fourth common voltage line SS4 through the second contact portion PCNT2, the common voltage ELVSS may be applied to the second pad unit AEP2.

As the second contact portion PCNT2 is provided to correspond to the protruding portion AEP2p, the second contact portion PCNT2 and the opening LDH may not overlap each other. In a plan view, the second contact portion PCNT2 and the opening LDH may be spaced apart from each other.

In a comparative example, when the second contact portion PCNT2 is disposed under the main portion AEP2m of the second pad unit AEP2 to overlap the opening LDH, a top surface of the main portion AEP2m of the second pad unit AEP2 may not be flat due to the second contact portion PCNT2. This may cause a measurement error as the top surface of the main portion AEP2m of the second pad unit AEP2 exposed through the opening LDH is not flat in a process of detecting a position of the opening LDH, which is a laser drilling hole, during a laser drilling process. Accordingly, in the second pad unit AEP2, the second pad unit PCNT2 and the opening LDH may not overlap each other.

In a plan view, the area of the opening LDH may be greater than the area of the second contact portion PCNT2.

The fourth common voltage line SS4 may be disposed under the second pad unit AEP2. The fourth common voltage line SS4 may extend substantially in the second direction (e.g., the y-axis direction) in a plan view. At least a part of the fourth common voltage line SS4 may overlap the second pad unit AEP2. In a pixel circuit area including the second pad unit AEP2, except for a structure of the fourth common voltage line SS4, wirings disposed in the same layer as the fourth common voltage line SS4, e.g., the first upper driving voltage line PL11, the third common voltage line SS3, and the fourth initialization voltage line VAL4, may be the same as those described with reference to FIG. 15. Accordingly, the difference related to the fourth common voltage line SS4 will be mainly described.

In the pixel circuit area including the second pad unit AEP2, the fourth common voltage line SS4 may include a first sub-common voltage line SS4a and a second sub-common voltage line SS4b. The first sub-common voltage line SS4a and the second sub-common voltage line SS4b may be disposed substantially side by side in a plan view. A connection portion SS4c connecting the first sub-common voltage line SS4a to the second sub-common voltage line SS4b may be disposed between the first sub-common voltage line SS4a and the second sub-common voltage line SS4b. Accordingly, the first sub-common voltage line SS4a and the second sub-common voltage line SS4b may be integrally formed (or unitary) to form one wide common voltage line. Such a structure of the fourth common voltage line SS4 may include one line in the 4X4 pixel unit structure described with reference to FIG. 8, for example. Because the fourth common voltage line SS4 has a wider width (area) than other common voltage lines, e.g., the first to third common voltage lines SS1, SS2, and SS3, described with reference to FIGS. 9 and 15, wiring resistance may be reduced and voltage drop in transmitting the common voltage ELVSS may be effectively reduced.

The connection portion SS4c connecting the first sub-common voltage line SS4a to the second sub-common voltage line SS4b may overlap the second pad unit AEP2. In an embodiment, as shown in FIGS. 20 and 21, the connection portion SS4c may cover an entirety of the surface of the second pad unit AEP2, for example. That is, the connection portion SS4c may be completely covered by the second pad unit AEP2.

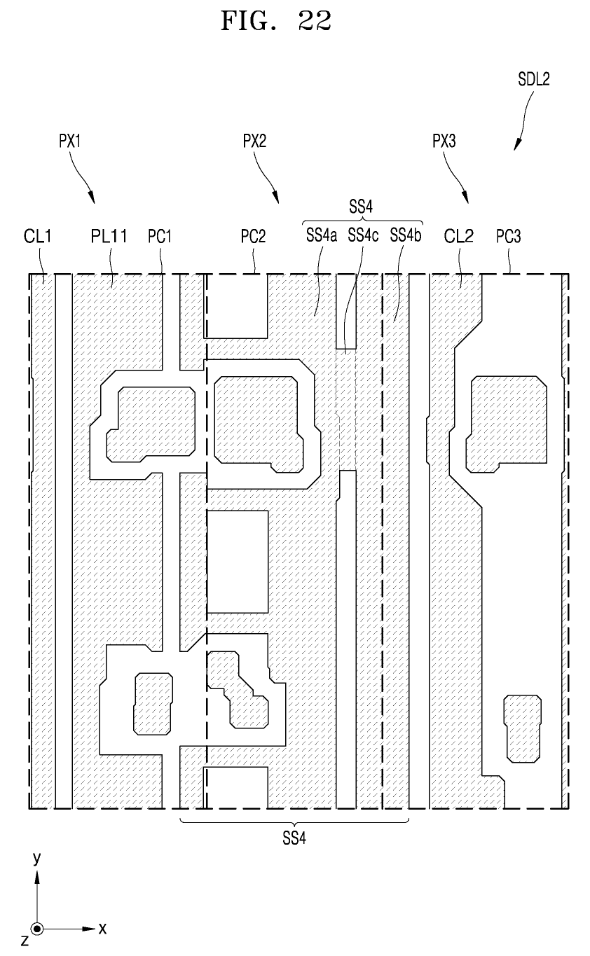

FIG. 22 is a cross-sectional view schematically illustrating an embodiment of a part of a display apparatus of the disclosure.

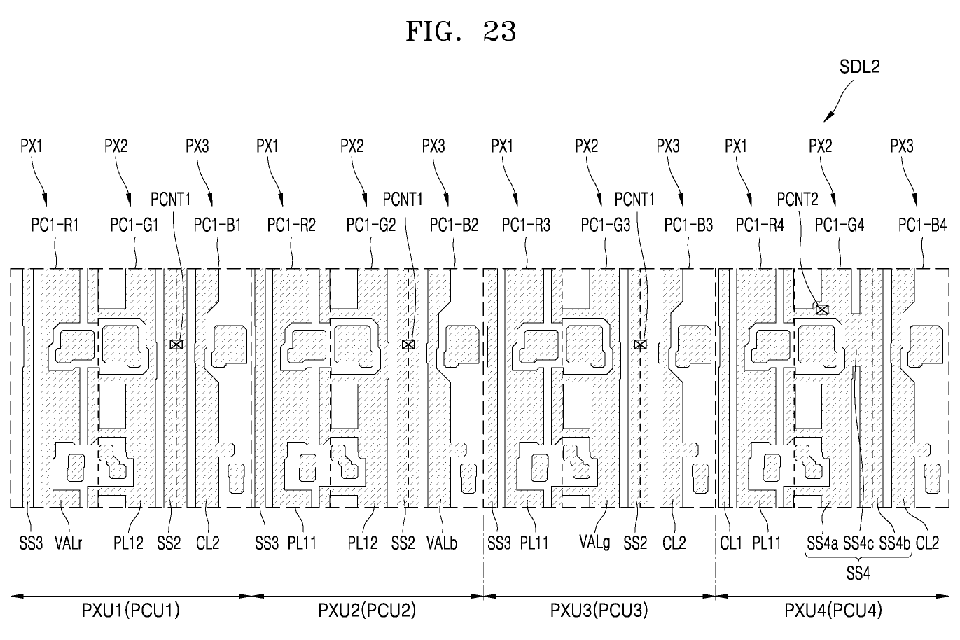

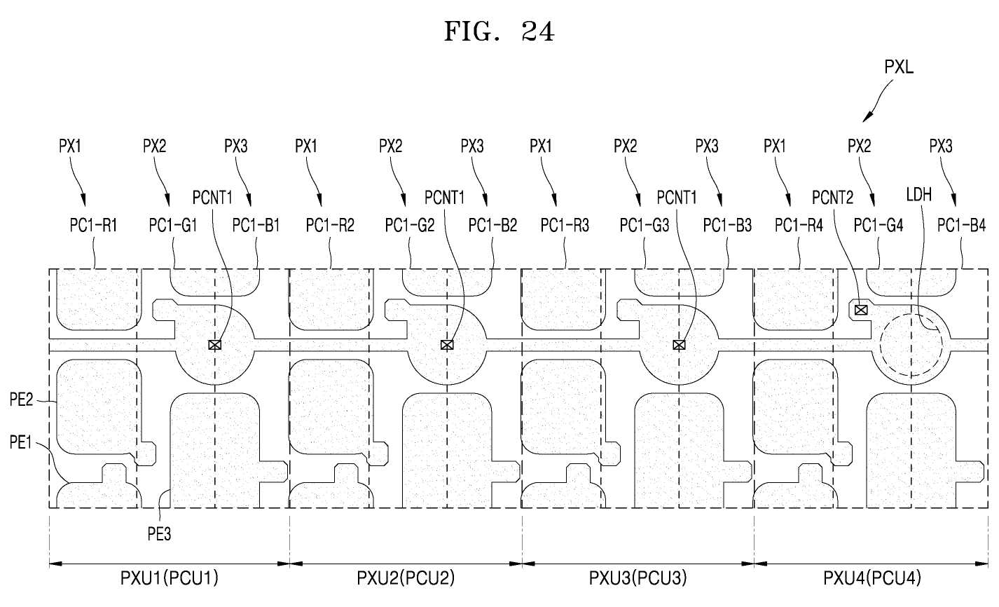

Referring to FIG. 22, in another embodiment, in the second source-drain layer SDL2, some wirings may have different functions from those described with reference to FIG. 15. This means that some wirings may function as wirings capable of transmitting other voltages or signals. In FIG. 22, the second source-drain layer SDL2 may include a first conductive line CL1 disposed on one side of the first upper driving voltage line PL11 and a second conductive line CL2 disposed on an opposite side of the fourth common voltage line SS4. The first conductive line CL1 and the second conductive line CL2 may respectively have the same shapes as the third common voltage line SS3 and the fourth initialization voltage line VAL4 described with reference to FIG. 15. However, in the illustrated embodiment, the driving voltage ELVDD may be applied to the first conductive line CL1 and the second conductive line CL2. Accordingly, the first conductive line CL1 and the second conductive line CL2 may function as driving voltage lines. In an embodiment, the second pad unit AEP2 (refer to FIG. 19) may be disposed in a pixel area including the second source-drain layer SDL2 of FIG. 22.FIG. 23 is a plan view schematically illustrating a second source-drain layer, in an embodiment of the disclosure, for example. FIG. 24 is a plan view schematically illustrating an embodiment of a pixel electrode layer of the disclosure. FIGS. 23 and 24 may correspond to a portion D of FIG. 8.

Referring to FIGS. 23 and 24, one pixel unit may include three pixels (e.g., PX1, PX2, and PX3). Each of the pixels (e.g., PX1, PX2, and PX3) may correspond to a sub-pixel. In an embodiment, one pixel unit may include the first pixel PX1 (i.e., first sub-pixel), the second pixel PX2 (i.e., second sub-pixel), and the third pixel PX3 (i.e., third sub-pixel), for example. The first pixel PX1 may include the first pixel circuit PC1, and a first light-emitting element such as a first light-emitting diode electrically connected to the first pixel circuit PC1 and emitting red light. The second pixel PX2 may include the second pixel circuit PC2, and a second light-emitting diode electrically connected to the second pixel circuit PC2 and emitting green light. The third pixel PX3 may include the third pixel circuit PC3, and a third light-emitting diode electrically connected to the third pixel circuit PC3 and emitting blue light.

FIGS. 23 and 24 illustrate a plurality of pixel units continuously disposed in the first direction (e.g., the x-axis direction). The plurality of pixel units may include a first pixel unit PXU1, a second pixel unit PXU2, a third pixel unit PXU3, and a fourth pixel unit PXU4 disposed in the first direction (e.g., the x-axis direction). The first pixel unit PXU1, the second pixel unit PXU2, the third pixel unit PXU3, and the fourth pixel unit PXU4 may be repeatedly disposed in the display area DA (refer to FIG. 8).

A first pixel PX1-R1 included in the first pixel unit PXU1 may include a first pixel circuit PC1-R1, a second pixel PX2-G1 included in the first pixel unit PXU1 may include a second pixel circuit PC2-G1, and a third pixel PX3-B1 included in the first pixel unit PXU1 may include a third pixel circuit PC3-B1. The first pixel circuit PC1-R1, the second pixel circuit PC2-G1, and the third pixel circuit PC3-B1 may constitute a first pixel circuit part PCU1.

A first pixel PX1-R2 included in the second pixel unit PXU2 may include a first pixel circuit PC1-R2, a second pixel PX2-G2 included in the second pixel unit PXU2 may include a second pixel circuit PC2-G2, and a third pixel PX3-B2 included in the second pixel unit PXU2 may include a third pixel circuit PC3-B2. The first pixel circuit PC1-R2, the second pixel circuit PC2-G2, and the third pixel circuit PC3-B2 may constitute a second pixel circuit part PCU2.

A first pixel PX1-R3 included in the third pixel unit PXU3 may include a first pixel circuit PC1-R3, a second pixel PX2-G3 included in the third pixel unit PXU3 may include a second pixel circuit PC2-G3, and a third pixel PX3-B3 included in the third pixel unit PXU3 may include a third pixel circuit PC3-B3. The first pixel circuit PC1-R3, the second pixel circuit PC2-G3, and the third pixel circuit PC3-B3 may constitute a third pixel circuit part PCU3.

A first pixel PX1-R4 included in the fourth pixel unit PXU4 may include a first pixel circuit PC1-R4, a second pixel PX2-G4 included in the fourth pixel unit PXU4 may include a second pixel circuit PC2-G4, and a third pixel PX3-B4 included in the fourth pixel unit PXU4 may include a third pixel circuit PC3-B4. The first pixel circuit PC1-R4, the second pixel circuit PC2-G4, and the third pixel circuit PC3-B4 may constitute a fourth pixel circuit part PCU4.

In the second source-drain layer SDL2 of FIG. 23, a plurality of wirings included in the second source-drain layer SDL2 may extend substantially in the second direction (e.g., the y-axis direction). Each of the plurality of wirings may perform a function of transmitting a voltage and/or a signal. In other words, the plurality of wirings having a repeated structure corresponding to the first pixel unit PXU1, the second pixel unit PXU2, the third pixel unit PXU3, and the fourth pixel unit PXU4 may perform the same function or different functions in each pixel unit. In the following description, the same wiring as that described with reference to FIGS. 8 to 22 is denoted by the same reference numeral and is described. Components denoted by the same reference numerals may have the same shape and function as described above without separate explanation.

First, in the first pixel unit PXU1, the second source-drain layer SDL2 of the first pixel circuit part PCU1 may include the second common voltage line SS2, the third common voltage line SS3, a first color initialization voltage line VALr, the second upper driving voltage line PL12, and the second conductive line CL2. The third common voltage line SS3 and the first color initialization voltage line VALr may be disposed to correspond to an area of the first pixel circuit PC1-R1. The second upper driving voltage line PL12 may be disposed to correspond to an area of the second pixel circuit PC1-G1, and a part thereof may be disposed across the area of the first pixel circuit PC1-R1. The second common voltage line SS2 may be disposed across the area of the second pixel circuit PC1-G1 and an area of the third pixel circuit PC1-B1. The second conductive line CL2 may be disposed to correspond to the area of the third pixel circuit PC1-B1. The first color initialization voltage line VALr may transmit an initialization voltage to each of the first pixels PX1-R1, PX1-R2, PX1-R3, and PX1-R4 disposed in the same row as shown in FIG. 23. The second conductive line CL2 is a vertical driving voltage line, and may transmit the driving voltage ELVDD to the third pixel PX1-B1 disposed in the same column.

In the second pixel unit PXU2, the second source-drain layer SDL2 of the second pixel circuit part PCU2 may include the second common voltage line SS2, the third common voltage line SS3, the first upper driving voltage line PL11, the second upper driving voltage line PL12, and a third color initialization voltage line VALb. The second pixel unit PXU2 is the same as that described with reference to FIGS. 9 to 16. That is, a portion illustrated in FIGS. 9 to 16 may be a portion where the second pixel unit PXU2 is disposed in FIG. 23. The third color initialization voltage line VALb may be the fourth initialization voltage line VAL4 described with reference to FIGS. 9 to 16. The third color initialization voltage line VALb may transmit an initialization voltage to each of the third pixels PX1-B1, PX1-B2, PX1-B3, and PX1-B4 disposed in the same row as shown in FIG. 23.

In the third pixel unit PXU3, the second source-drain layer SDL2 of the third pixel circuit part PCU3 may include the second common voltage line SS2, the third common voltage line SS3, a second color initialization voltage line VALg, the first upper driving voltage line PL11, and the second conductive line CL2. The third common voltage line SS3 and the first upper driving voltage line PL11 may be disposed to correspond to an area of the first pixel circuit PC1-R3. The second color initialization voltage line VALg may be disposed to correspond to an area of the second pixel circuit PC1-G3, and a part thereof may be disposed across the area of the first pixel circuit PC1-R3. The second common voltage line SS2 may be disposed across the area of the second pixel circuit PC1-G1 and an area of the third pixel circuit PC1-B1. The second conductive line CL2 may be disposed to correspond to the area of the third pixel circuit PC1-B1. The second color initialization voltage line VALg may transmit an initialization voltage to each of the second pixels PX1-G1, PX1-G2, PX1-G3, and PX1-G4 disposed in the same row as shown in FIG. 23. The second conductive line CL2 is a vertical driving voltage line and may transmit the driving voltage ELVDD to the third pixel PX1-B3 disposed in the same column.

In the fourth pixel unit PXU4, the second source-drain layer SDL2 of the fourth pixel circuit part PCU4 may include the first conductive line CL1, the first upper driving voltage line PL11, the fourth common voltage line SS4, and the second conductive line CL2. The fourth pixel unit PXU4 is the same as that described with reference to FIGS. 20 to 22. That is, a portion illustrated in FIGS. 20 to 22 may be a portion where the fourth pixel unit PXU4 is disposed in FIG. 23.

In the pixel electrode layer PXL of FIG. 24, the auxiliary electrode AE may be disposed between a plurality of pixel electrodes (e.g., PE, PE2, and PE3). The auxiliary electrode AE may be also referred to as the first common voltage line SS1, and the first common voltage line SS1 may extend substantially in the first direction (e.g., the x-axis direction). The first common voltage line SS1 may include the pad unit AEP disposed to correspond to each of the first pixel unit PXU1, the second pixel unit PXU2, the third pixel unit PXU3, and the fourth pixel unit PXU4, and the pad units AEP may be connected to each other through an extension portion AEPa.

As described with reference to FIGS. 15 and 16, the second common voltage line SS2 may be electrically connected to the pad unit AEP of the first common voltage line SS1 disposed thereon. In FIG. 23, the second common voltage line SS2 may be provided in each of the first pixel unit PXU1, the second pixel unit PXU2, the third pixel unit PXU3, and the fourth pixel unit PXU4. The fourth common voltage line SS4 may be provided in the fourth pixel unit PXU4, and in the fourth pixel unit PXU4, the fourth common voltage line SS4 may be electrically connected to the pad unit AEP of the first common voltage line SS1, like the second common voltage line SS2.

However, in the fourth common voltage line SS4 of the fourth pixel unit PXU4, the first sub-common voltage line SS4a and the second sub-common voltage line SS4b may be connected to each other, unlike the second common voltage line SS2 in the first pixel unit PXU1. As described with reference to FIGS. 20 to 22, this may be an attempt to increase the width (area) of the fourth common voltage line SS4, reduce wiring resistance, and prevent a position of the opening LDH (refer to FIG. 20) formed as a laser drilling point from overlapping a position of the second contact portion PCNT2. Accordingly, in each of the first pixel unit PXU1, the second pixel unit PXU2, and the third pixel unit PXU3, the first contact portion PCNT1 may be disposed on the second common voltage line SS2, and in the fourth pixel unit PXU4, the second contact portion PCNT2 may be disposed on the fourth common voltage line SS4.

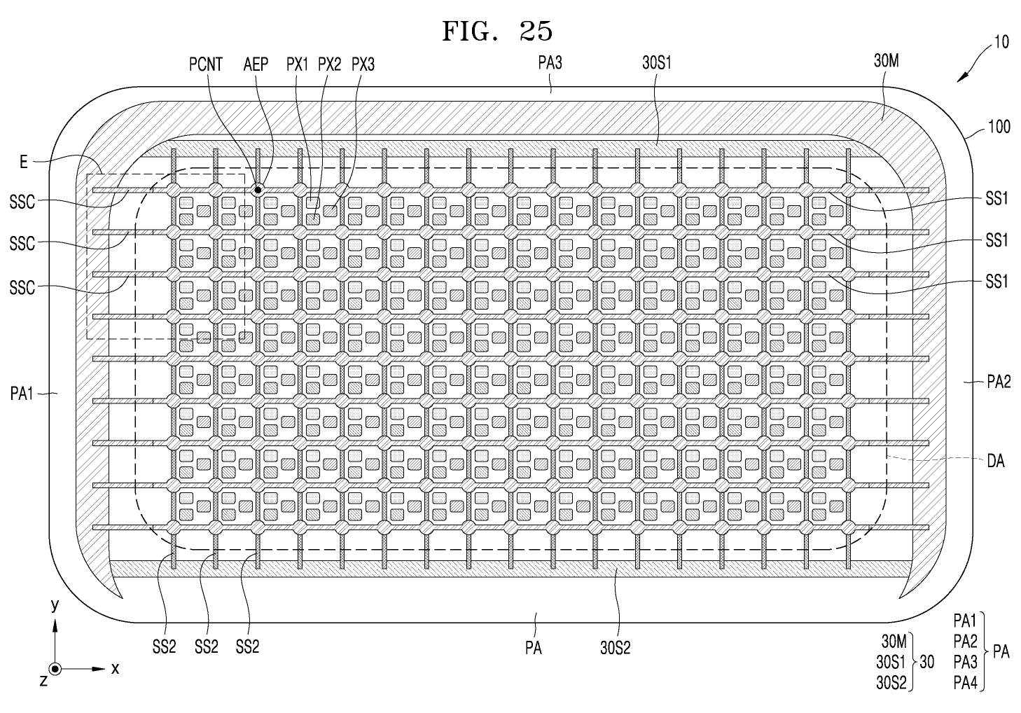

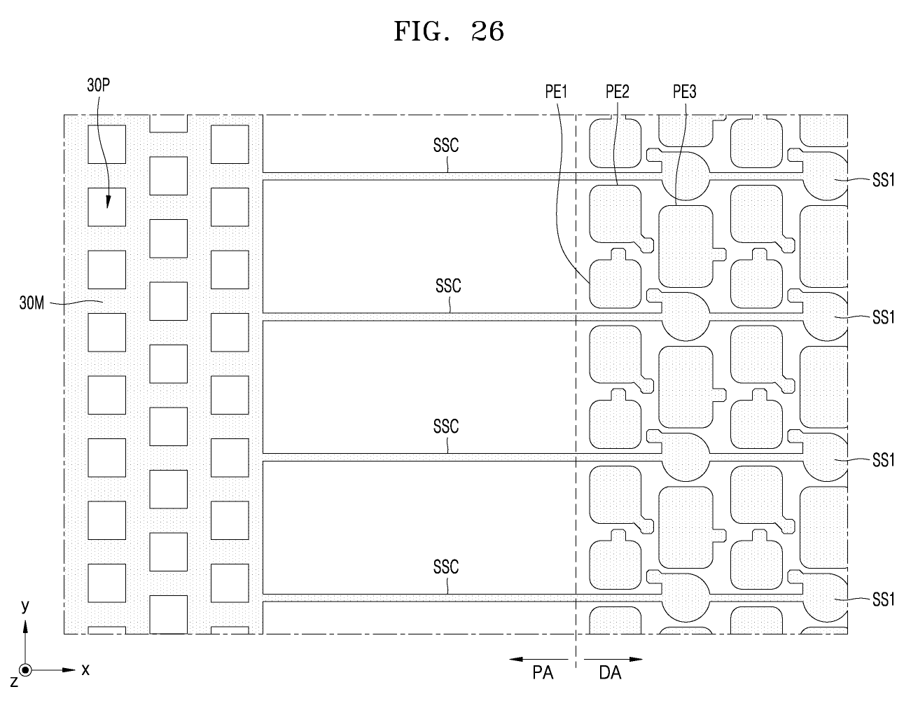

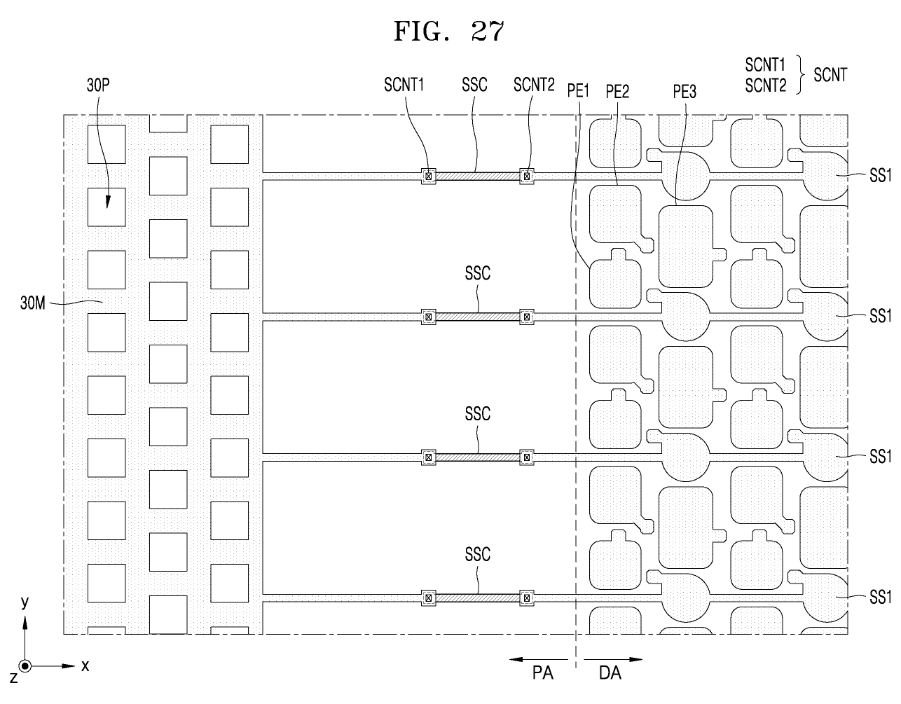

FIG. 25 is a plan view schematically illustrating an embodiment of a display apparatus of the disclosure. FIGS. 26 and 27 are enlarged views schematically illustrating a part of the display apparatus of FIG. 25. Each of FIGS. 26 and 27 may correspond to a portion E of FIG. 25.

Referring to FIG. 25, the display apparatus 10 may include the display area DA where an image is displayed and the peripheral area PA outside the display area DA. The display area DA may be entirely surrounded by the peripheral area PA.

In the display area DA, the first to third pixels PX1, PX2, and PX3 may be disposed. The first to third pixels PX1, PX2, and PX3 may each be a sub-pixel, and may constitute one pixel unit. The first to third pixels PX1, PX2, and PX3 may be arranged in any of various shapes such as a stripe arrangement, a pentile arrangement, a diamond arrangement, or a mosaic arrangement to display an image. Each of the first to third pixels PX1, PX2, and PX3 may include a light-emitting diode, and may emit light, e.g., red light, green light, blue light, or white light, through the light-emitting diode. In an embodiment, the first pixel PX1 may emit red light, the second pixel PX2 may emit green light, and the third pixel PX3 may emit blue light, for example.

The peripheral area PA may include the first peripheral area PA1, the second peripheral area PA2, the third peripheral area PA3, and the fourth peripheral area PA4. The first peripheral area PA1 and the second peripheral area PA2 may be disposed on one side and an opposite side (e.g., a left side and a right side) with the display area DA therebetween. The third peripheral area PA3 and the fourth peripheral area PA4 may be disposed to connect the first peripheral area PA1 to the second peripheral area P2 with the display area DA therebetween. The third peripheral area PA3 and the fourth peripheral area PA4 may be disposed on an upper side and a lower side with the display area DA therebetween.

In the peripheral area PA, the common voltage supply line 30 may be disposed. In addition, as described with reference to FIG. 6, in the peripheral area PA, outer circuits such as driving circuits electrically connected to the pixels (e.g., PX1, PX2, and PX3) and the driving voltage supply line 20 (refer to FIG. 6) may be further disposed.

The common voltage supply line 30 may be disposed along an outer edge of the display area DA. The common voltage supply line 30 may be spaced apart from the display area DA by a predetermined interval. The common voltage supply line 30 may partially or surround an entirety of the display area DA. The common voltage supply line 30 may include a main voltage line 30M, a first sub-voltage line 30S1, and a second sub-voltage line 30S2. The main voltage line 30M may be a main common voltage supply line. The main voltage line 30M may be disposed in a loop shape with one side open, to partially surround the display area DA in the first to third peripheral areas PA1, PA2, and PA3.

The first sub-voltage line 30S1 may be disposed in the third peripheral area PA3, and may extend in the first direction (e.g., the x-axis direction). That is, the first sub-voltage line 30S1 may be a horizontal common voltage supply line. The first sub-voltage line 30S1 may be disposed between the display area DA and the main voltage line 30M in the third peripheral area PA3. Each of one side and an opposite side of the first sub-voltage line 30S1 may contact the main voltage line 30M, and thus, the first sub-voltage line 30S1 may be electrically connected to the main voltage line 30M.

The second sub-voltage line 30S2 may be disposed in the fourth peripheral area PA4 and may extend in the first direction (e.g., the x-axis direction). That is, the second sub-voltage line 30S2 may be a horizontal common voltage supply line. The second sub-voltage line 30S2 may be disposed in the fourth peripheral area PA4 to be next (adjacent) to the display area DA. Each of one side and an opposite side of the second sub-voltage line 30S2 may contact the main voltage line 30M, and thus, the second sub-voltage line 30S2 may be electrically connected to the main voltage line 30M. As described above, as an end of each of the first sub-voltage line 30S1 and the second sub-voltage line 30S2 is electrically connected to the main voltage line 30M, the common voltage supply line 30 may be provided in a closed loop shape electrically surrounding the display area DA.

The first sub-voltage line 30S1 and the second sub-voltage line 30S2 may be disposed in a different layer from the main voltage line 30M. In an embodiment, the main voltage line 30M may be provided in the same layer and include the same material as that of the pixel electrode layer PXL described with reference to FIG. 16. When the main voltage line 30M is disposed in the same layer as the pixel electrode layer PXL, it may mean that the main voltage line 30M is simultaneously patterned with the same mask during a process of forming the pixel electrode layer PXL of FIG. 16. The first sub-voltage line 30S1 and the second sub-voltage line 30S2 may be provided in the same layer as the first source-drain layer SD1 described with reference to FIG. 14 to include the same material as each other. When the first sub-voltage line 30S1 and the second sub-voltage line 30S2 are disposed in the same layer as the first source-drain layer SD1, it may mean that the first sub-voltage line 30S1 and the second sub-voltage line 30S2 are simultaneously patterned with the same mask during a process of forming the first source-drain layer SD1 of FIG. 14.

In another embodiment, the first sub-voltage line 30S1 and the second sub-voltage line 30S2 may be disposed in different layers. In an embodiment, the first sub-voltage line 30S1 (or the second sub-voltage line 30S2) may be provided in the same layer as the first source-drain layer SD1 of FIG. 14 to include the same material, and the second sub-voltage line 30S2 (or the first sub-voltage line 30S1) may be provide in the same layer as the second source-drain layer SD2 of FIG. 15 to include the same material, for example. In an alternative embodiment, at least one of the first sub-voltage line 30S1 and the second sub-voltage line 30S2 may be provided in the same layer as the gate line GAT of FIG. 13 to include the same material as each other.

In the display area DA, the first common voltage line SS1 and the second common voltage line SS2 may be disposed. The first common voltage line SS1 may extend in the first direction (e.g., the x-axis direction) across the entirety of the surface of the display area DA, and the second common voltage line SS2 may extend in the second direction (e.g., the y-axis direction) across the entirety of the surface of the display area DA. The first common voltage line SS1 and the second common voltage line SS2 may be electrically connected through the contact portion PCNT at the pad unit AEP where the first common voltage line SS1 and the second common voltage line SS2 overlap as described with reference to FIG. 16. The first common voltage line SS1 and the second common voltage line SS2 may form a mesh structure in the entirety of the surface of the display area DA.

The second common voltage line SS2 may extend in the second direction (e.g., the y-axis direction) across the entirety of the surface of the display area DA, and a part thereof may further extend to the peripheral area PA. In other words, one end of the second common voltage line SS2 may extend in the +y direction to be disposed in the third peripheral area PA3, and an opposite end of the second common voltage line SS2 may extend in the -y direction to be disposed in the fourth peripheral area PA4. The end of the second common voltage line SS2 extending to the third peripheral area PA3 may be electrically connected to the first sub-voltage line 30S1 disposed in the third peripheral area PA3. An opposite end of the second common voltage line SS2 extending to the fourth peripheral area PA4 may be electrically connected to the second sub-voltage line 30S2 disposed in the fourth peripheral area PA4.

In an embodiment, the first common voltage line SS1 may extend in the first direction (e.g., the x-axis direction) across the entirety of the surface of the display area DA, and a part thereof may further extend to the peripheral area PA. In other words, one end of the first common voltage line SS1 may extend in a +x direction to be disposed in the second peripheral area PA2, and an opposite end of the first common voltage line SS1 may extend in the -x direction to be disposed in the first peripheral area PA1. The end of the first common voltage line SS1 extending to the second peripheral area PA2 may be electrically connected to the common voltage supply line 30, that is, the main voltage line 30M, disposed in the second peripheral area PA2. An opposite end of the first common voltage line SS1 extending to the first peripheral area PA1 may be electrically connected to the common voltage supply line 30, that is, the main voltage line 30M, disposed in the first peripheral area PA1.

In order for the first common voltage line SS1 to be connected to the common voltage supply line 30 in the peripheral area PA, a connection line SSC may be provided between the first common voltage line SS1 and the common voltage supply line 30. The connection line SSC may extend substantially in the first direction (e.g., the x-axis direction), like the first common voltage line SS1.

Referring to FIG. 26, the connection line SSC may be integrally formed (or unitary) with the first common voltage line SS1. When the connection line SSC is integrally formed (or unitary) with the first common voltage line SS1, it may mean that the first common voltage line SS1 extends in the first direction (e.g., the x-axis direction) toward the peripheral area PA, and one end of the extended first common voltage line SS1 is connected to the main voltage line 30M. In this case, the connection line SSC may be a portion of the first common voltage line SS1. When the main voltage line 30M includes the same material as that of the pixel electrode layer PXL (refer to FIG. 16) as described above, the first common voltage line SS1 including the connection line SSC the main voltage line 30M may be integrally formed (or unitary).

Referring to FIG. 27, the connection line SSC may include a conductive layer separate from the first common voltage line SS1. When the connection line SSC includes a conductive layer separate from the first common voltage line SS1, it may mean that the connection line SSC and the first common voltage line SS1 are disposed in different layers, and the connection line SSC and the first common voltage line SS1 are electrically connected to each other through the contact hole SCNT defined in at least one insulating layer (e.g., organic insulating layer) disposed between the connection line SSC and the first common voltage line SS1. In an embodiment, the contact hole SCNT may include a first contact hole SCNT1 though which the connection line SSC and the main voltage line 30M contact each other, and a second contact hole SCNT2 through which connection line SSC and the first common voltage line SS1 contact each other. In an embodiment, the first common voltage line SS1 may include the same material as that of the pixel electrode layer PXL (refer to FIG. 16), and the connection line SSC may include the same material as that of the second source-drain layer SDL2 (refer to FIG. 15), for example. In an alternative embodiment, the first common voltage line SS1 may include the same material as that of the pixel electrode layer PXL (refer to FIG. 16), and the connection line SSC may include the same material as that of the first source-drain layer SD1 (refer to FIG. 14). In an alternative embodiment, the first common voltage line SS1 may include the same material as that of the pixel electrode layer PXL (refer to FIG. 16), and the connection line SSC may include the same material as that of the gate layer GAT (refer to FIG. 13).In an embodiment, as shown in FIGS, for example. 26 and 27, a plurality of holes 30P may be defined in the main voltage line 30M. Although each of the plurality of holes 30P has a quadrangular shape in FIGS. 26 and 27, a shape of each of the plurality of holes 30P may be modified in various ways. The main voltage line 30M may have a greater width than other voltage lines, e.g., the first sub-voltage line 30S1 and the second sub-voltage line 30S2, as shown in FIG. 25. Accordingly, when the plurality of holes 30P are defined in the main voltage line 30M to remove a part of the main voltage line 30M in a corresponding area, efficient out-gassing may be facilitated from an organic insulating layer disposed under the main voltage line 30M.

In embodiments of the disclosure, a display apparatus and an electronic device capable of providing a high-quality image while reducing power consumption may be provided. The effects described above are examples, and the effects of the disclosure are not limited thereto.

While the disclosure has been particularly shown and described with reference to embodiments thereof, they are provided for the purposes of illustration and it will be understood by one of ordinary skill in the art that various modifications and equivalent other embodiments made be made from the disclosure. Accordingly, the true technical scope of the disclosure is defined by the technical spirit of the appended claims.

What is claimed is:

1. A display apparatus comprising:
a substrate comprising:
a display area in which a first pixel and a second pixel which respectively emit light of different wavelengths from each other are disposed; and
a peripheral area outside the display area;
a first common voltage line disposed in the display area, extending in a first direction, and comprising:
a plurality of pad units spaced apart from each other by a predetermined interval;
a second common voltage line disposed in the display area, extending in a second direction intersecting the first direction and overlapping the second pixel; and
a third common voltage line disposed in the display area, extending in the second direction and overlapping the first pixel,
wherein the second common voltage line is electrically connected to the plurality of pad units of the first common voltage line through a contact portion in an area where the second common voltage line overlaps the plurality of pad units.

2. The display apparatus of claim 1, wherein the second pixel is provided in plural,
wherein the plurality of pad units are alternately arranged with the plurality of second pixels arranged in the second direction.

3. The display apparatus of claim 1, wherein the second pixel emits light having a blue wavelength.

4. The display apparatus of claim 1, wherein an organic insulating layer is disposed between the first common voltage line and the second common voltage line,
wherein the contact portion is provided by a contact hole defined in the organic insulating layer.

5. The display apparatus of claim 1, wherein the plurality of pad units comprise a first pad unit and a second pad unit,
wherein a first contact portion corresponding to the first pad unit is disposed at a central portion of the first pad unit.

6. The display apparatus of claim 5, wherein the second pad unit comprises a protruding portion protruding in at least one direction,
wherein a second contact portion corresponding to the second pad unit is disposed in the protruding portion.

7. The display apparatus of claim 6, wherein at least one insulating layer is further disposed on the plurality of pad units,
wherein an opening through which a central portion of the second pad unit is exposed is defined in the at least one insulating layer.

8. The display apparatus of claim 7, wherein, in a plan view, an area of the opening is greater than an area of the second contact portion.

9. The display apparatus of claim 7, wherein, in a plan view, the second contact portion and the opening are spaced apart from each other.

10. The display apparatus of claim 7, further comprising a fourth common voltage line overlapping at least a part of the opening and extending in the second direction, in a plan view.

11. The display apparatus of claim 10, wherein the fourth common voltage line comprises a first sub-common voltage line and a second sub-common voltage line, and the first sub-common voltage line and the second sub-common voltage line comprise a connection portion which connects the first sub-common voltage line to the second sub-common voltage line in a partial region.

12. The display apparatus of claim 11, wherein the connection portion overlaps the second pad unit.

13. The display apparatus of claim 1, wherein the second pixel has a second emission area,
wherein, in a plan view, the second common voltage line is disposed in a symmetric shape passing through a central portion of the second emission area of the second pixel.

14. The display apparatus of claim 1, further comprising a first upper driving voltage line and a second upper driving voltage line disposed in the display area, extending in the second direction, and spaced apart from each other in a plan view, wherein a plurality of openings are defined in the second upper driving voltage line, and wherein each of the plurality of openings is defined between a first emission area of the first pixel and a second emission area of the second pixel.

15. The display apparatus of claim 1, wherein the first pixel comprises a first light-emitting element and a first pixel circuit,
wherein the first light-emitting element comprises a first pixel electrode, a counter electrode disposed on the first pixel electrode, and an intermediate layer comprising an emission layer disposed between the first pixel electrode and the counter electrode,
wherein the first common voltage line has a same material as a material of the first pixel electrode, wherein the first pixel circuit comprises:
a thin-film transistor comprising a semiconductor layer, a gate electrode having at least a part overlapping the semiconductor layer, and a first conductive layer disposed on the gate electrode and electrically connected to the semiconductor layer; and
a second conductive layer disposed on the thin-film transistor,
wherein the second common voltage line comprises a same material as a material of the second conductive layer.

16. The display apparatus of claim 15, wherein the third common voltage line comprises a same material as the material of the second conductive layer.

17. The display apparatus of claim 1, wherein the second common voltage line and the third common voltage line are disposed in a same layer.

18. The display apparatus of claim 1, further comprising a common voltage supply line disposed in the peripheral area and disposed along an outer edge of the display area,
wherein the first common voltage line further comprises a connection line extending in the first direction toward the peripheral area and electrically connected to the common voltage supply line.

19. An electronic device comprising:
a display apparatus comprising:
a substrate comprising a display area and a peripheral area outside the display area, wherein in the display area, a first pixel and a second pixel emitting light of different wavelengths are disposed;
a first common voltage line disposed in the display area, extending in a first direction, and comprising a plurality of pad units spaced apart from each other by a predetermined interval;
a second common voltage line disposed in the display area, extending in a second direction intersecting the first direction and overlapping the second pixel; and
a third common voltage line disposed in the display area, extending in the second direction and overlapping the first pixel; and
a housing in which the display apparatus is accommodated,
wherein the second common voltage line is electrically connected to the plurality of pad units of the first common voltage line through a contact portion in an area where the second common voltage line overlaps the plurality of pad units.

20. The electronic device of claim 19, further comprising a processor,
wherein the display apparatus further comprises a controller configured to receive a power control signal from the processor and output a control signal based on the power control signal, and a power supply circuit configured to generate a driving voltage based on the control signal of the controller.
